(19) United States
(12) Patent Application Publication
(10) Pub. No.: US 2013/0319861 A1
(43) Pub. Date: Dec. 5, 2013

(54) Outputting A Droplet Of Liquid Medium From A Device For Processing Micro-Objects In The Medium

(71) Applicant: BERKELEY LIGHTS, INC., Emeryville, CA (US)

(72) Inventors: Igor Y. Khandros, Orinda (CA); Gaetan L. Mathieu, Varennes (CA); J. Tanner Nevill, El Cerrito, CA (US); Ming C. Wu, Moraga, CA (US)

(73) Assignee: Berkeley Lights, Inc., Emeryville, CA (US)

(21) Appl. No.: 13/856,781

(22) Filed: Apr. 4, 2013

Related U.S. Application Data
(60) Provisional application No. 61/653,322, filed on May 30, 2012.

(51) Int. Cl. B81B 1/00; B03C 5/02; B03C 5/00

(52) U.S. Cl. CPC B81B 1/00; B03C 5/005; B03C 5/022
USPC 204/452; 204/603

(57) ABSTRACT

A micro-fluidic device can include a processing mechanism for processing micro-objects in a liquid medium and an outputting mechanism for expressing from the device a droplet of the medium containing one or more of the micro-objects. The outputting mechanism can include an expressing mechanism having a reservoir for holding a quantity of the liquid medium and a striking mechanism for striking and compressing the expressing mechanism to express a droplet of the medium from the expressing mechanism.

### CROSS REFERENCE TO RELATED APPLICATION(S)

This application is a non-provisional (and thus claims the benefit) of U.S. provisional patent application Ser. No. 61/653,322 (filed May 30, 2012), which is incorporated by reference herein in its entirety.

### BACKGROUND

Micro-objects such as biological cells and micro-particles can be suspended in a liquid medium and moved through fluidic circuit elements of a micro-fluidic device. The present invention is directed to improved micro-fluidic devices and processes for processing micro-objects and expressing one or more of the micro-objects from the device.

### SUMMARY

In some embodiments of the invention, a process of expressing a micro-object in a droplet of liquid medium can include moving a micro-object into an expressing mechanism disposed on a base, which can have an output passage. The process can also include expressing the micro-object in a droplet of the medium through the output passage. The droplet can be expressed by striking the expressing mechanism with sufficient force to express the droplet through the output passage.

In some embodiments of the invention, a micro-fluidic device can include an expressing mechanism and a striking mechanism. The expressing mechanism can be disposed on a base that has an output passage. The striking mechanism can be configured to strike the expressing mechanism with sufficient force to express a droplet of liquid medium through the output passage.

### BRIEF DESCRIPTION OF THE DRAWINGS

FIG. 1A illustrates an example of a processing/outputting micro-fluidic device according to some embodiments of the invention.

FIG. 1B illustrates a cross-sectional side view of the processing/outputting device of FIG. 1A.

FIG. 1C illustrates the cross-sectional side view of the processing/outputting device of FIG. 1B showing output of a droplet according to some embodiments of the invention.

FIG. 2 shows a partial perspective view of the processing/outputting device of FIG. 1A in which the processing mechanism comprises micro-fluidic channels according to some embodiments of the invention.

FIG. 3A illustrates a top partial view and FIG. 3B a side partial view of the processing/outputting device of FIG. 1A showing an example of a channel that widens at and/or near the output mechanism according to some embodiments of the invention.

FIG. 4 shows a cross-sectional side view of the processing/outputting device of FIG. 1A in which the processing mechanism comprises an optoelectronic tweezers (OET) device according to some embodiments of the invention.

FIG. 5 illustrates a partial top view of the photoconductive layer of the OET device of FIG. 4 and a light cage around a selected micro-object according to some embodiments of the invention.

FIG. 6 illustrates a partial top view of the photoconductive layer of the OET device of FIG. 4 and a light cage around selected micro-objects according to some embodiments of the invention.

FIG. 7A illustrates a cross-sectional side view of an example of the outputting mechanism of the processing/outputting device of FIG. 1A according to some embodiments of the invention.

FIG. 7B shows a striking mechanism compressing an expressing mechanism of the outputting mechanism of FIG. 7A, which expresses a droplet of medium according to some embodiments of the invention.

FIG. 8 illustrates an example of a striking mechanism in which a hammer strikes and compresses an expressing mechanism according to some embodiments of the invention.

FIG. 9 illustrates an example of a striking mechanism in which a single hammer is configured to strike multiple expressing mechanisms according to some embodiments of the invention.

FIG. 10 illustrates an example of a striking mechanism in which multiple hammers are attached to a single actuator according to some embodiments of the invention.

FIGS. 11A and 11B show an example of a striking mechanism comprising an actuator and a spring according to some embodiments of the invention.

FIGS. 12A and 12B show an example of an expressing mechanism comprising a reservoir that is larger than the output passage according to some embodiments of the invention.

FIGS. 13A and 13B illustrate an example of an expressing mechanism comprising a reservoir with slopped sidewalls according to some embodiments of the invention.

FIGS. 14A, 14B, and 14C are perspective and cross-sectional views of a processing/outputting micro-fluidic device in which reservoirs are spaced a distance from corresponding output passages in a base of the device according to some embodiments of the invention.

FIGS. 15, 16, and 17 show cross-sectional side views of examples of the output passage in the base of the processing/outputting device of FIG. 1A according to some embodiments of the invention.

FIG. 18 shows an example of a barrier disposed adjacent the output passage in the base of the processing/outputting device of FIG. 1A according to some embodiments of the invention.

FIGS. 19A, 19B, and 19C illustrate an example of an expressing mechanism and output passages through the base according to some embodiments of the invention.

FIG. 20 illustrates flow of the medium in the expressing mechanism and output passages of FIGS. 19A-19C according to some embodiments of the invention.

FIG. 21 shows a striking mechanism striking and compressing a flexible structure and thereby flowing medium through both output passages in the base to express a droplet according to some embodiments of the invention.

FIG. 22A illustrates another example of a striking mechanism and an expressing mechanism according to some embodiments of the invention.

FIG. 22B illustrates a cross-sectional side view of the striking mechanism and the expressing mechanism of FIG. 22A.

FIG. 22C illustrates a bottom view of the flexible structure of the expressing mechanism of FIG. 22B.

FIG. 23 shows the expressing mechanism of FIGS. 22A-22C expressing a droplet according to some embodiments of the invention.

FIG. 24A illustrates an example of an expressing mechanism as part of a micro-fluidic channel according to some embodiments of the invention.

FIG. 24B illustrates a cross-sectional side view of the expressing mechanism and micro-fluidic channel of FIG. 24A.

FIG. 24C shows the expressing mechanism and micro-fluidic channel of FIG. 24A expressing a droplet according to some embodiments of the invention.

FIG. 25A illustrates another example of an expressing mechanism as part of a micro-fluidic channel according to some embodiments of the invention.

FIG. 25B illustrates a cross-sectional side view of the expressing mechanism and micro-fluidic channel of FIG. 25A.

FIG. 25C shows the expressing mechanism and micro-fluidic channel of FIG. 25A expressing a droplet according to some embodiments of the invention

FIG. 26 illustrates an example of a processing/outputting device with a plurality of outputting mechanisms according to some embodiments of the invention.

FIG. 27 is a top view of the processing/outputting device of FIG. 26 showing a combination of a physical channel and multiple virtual channels according to some embodiments of the invention.

FIGS. 28 and 29 illustrate examples of processing/outputting devices disposed in cascaded arrangements according to some embodiments of the invention.

FIG. 30A shows an exploded perspective view and FIG. 30B shows a side, cross-sectional view of another processing/outputting micro-fluidic device according to some embodiments of the invention.

FIG. 31 a process illustrating an example of operation of any of the outputting/processing devices disclosed herein according to some embodiments of the invention.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on,” “attached to,” or “coupled to” are used herein, one element (e.g., an object, material, layer, substrate, medium, etc.) can be “on,” “attached to,” or “coupled to” another element regardless of whether the one element is directly on, attached, or coupled to the other element or there are one or more intervening elements between the one element and the other element. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

As used herein, “substantially” means sufficient to work for the intended purpose. When used with respect to an angular orientation, position, or measurement (e.g., perpendicular, parallel), “substantially” means within ten degrees. The term “ones” means more than one.\

As used herein, the term “micro-object” can encompass one or more of the following: inanimate micro-objects such as micro-particles, micro-beads, micro-wires, and the like; biological micro-objects such as cells (e.g., proteins, embryos, plasmids, oocytes, sperms, hydridomas, and the like); and/or a combination of inanimate micro-objects and biological micro-objects (e.g., micro-beads attached to cells).

As used herein, the meaning of the term “processing” a micro-object includes any one or more of the following: moving (e.g., in a flow of liquid medium, with an OET device, or the like), sorting, and/or selecting one or more of the micro-objects; modifying one or more of the micro-objects, wherein examples of such modifying include growing populations of micro-objects that are cells or other living biological entities, fusing two or more such micro-objects together, and transfecting one or more micro-objects; monitoring micro-objects; monitoring growth, secretions, or the like of micro-objects that are cells or other living biological entities; and/or delivering one or more of the micro-objects to an outputting mechanism.

As used herein, “strike” means to cause a striking element to undergo a motion that causes the striking element to be brought into sudden and abrupt contact with a struck element, which applies a sudden and abrupt force to the struck element.

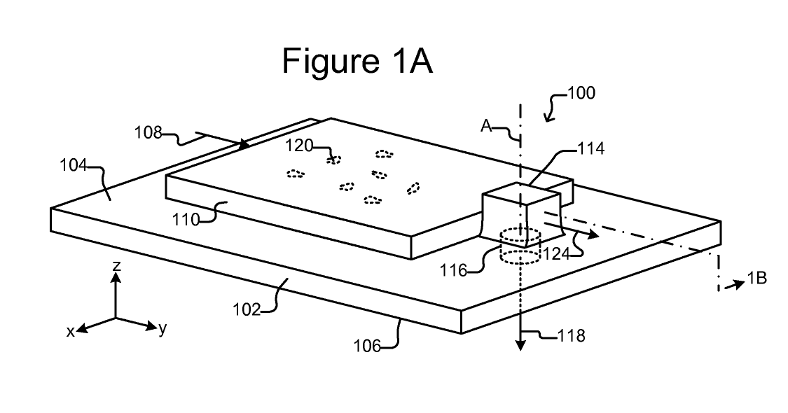

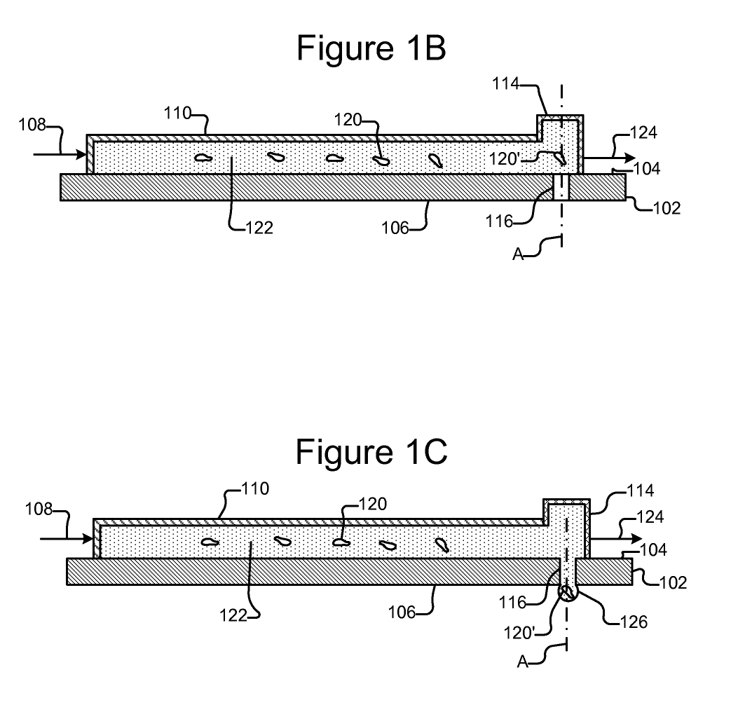

In some embodiments of the invention, a processing/outputting micro-fluidic device can comprise an outputting mechanism for expressing a droplet of a liquid medium, which can contain one or more micro-objects. The device can also comprise a processing mechanism by which the micro-objects can be manipulated. FIGS. 1A-1C illustrate an example of such a processing/outputting device 100 according to some embodiments of the invention.

As shown in FIGS. 1A-1C, the processing/outputting micro-fluidic device 100 can comprise a base 102, a processing mechanism 110, and an outputting mechanism 114. The processing mechanism 110 can process (as defined above) micro-objects 120 suspended in a liquid medium 122. The medium 122 can be generally disposed in a plane (e.g., the “x, y” plane in FIGS. 1A-1C), which can, in some embodiments, correspond to an upper surface 104 of the base 102. For example, the medium 122 can be disposed on the upper surface 104, and the processing mechanism 110 can process micro-objects 120 in the medium 122 on the upper surface 104. Alternatively, the processing mechanism 110 can be disposed on the upper surface 104, and the medium 122 can be disposed in the processing mechanism 110 on an inner surface (not shown) of the processing mechanism 110. In such an embodiment, the processing mechanism 110 can process the micro-objects 120 in the medium 122 on the inner surface (not shown) of the processing mechanism 110. The plane in which the medium 122 is disposed can be the upper surface 104 of the base 102 or the inner surface (not shown) of the processing mechanism 110.

Regardless, the processing performed by the processing mechanism 110 can include, among the many functions noted above in defining the term “processing,” selecting one or a specific number of the micro-objects 120 and moving the selected micro-object(s) 120 into the outputting mechanism 114. The outputting mechanism 114 can then output 118 the selected micro-object(s) 120 in a droplet 126 of the medium 122 from the outputting mechanism 114 in a direction that is out of the plane in which the micro-object(s) 120 were processed by the processing mechanism 110 (the “x, y” plane in FIGS. 1A-1C), which as noted can be the plane of a surface (e.g., the upper surface 104 of the base 102, an inner surface (not shown) of the processing mechanism 110, or the like) on which the medium 122 is disposed. For example, the outputting mechanism 114 can output the micro-object(s) 120′ in a droplet 126 of the medium 122 through an output passage 116 (e.g., a hole, a nozzle, or the like) in the base 102 as shown in FIG. 1C. Of course, the outputting mechanism 114 need not output every micro-object 120 in a droplet 126; rather, a micro-object 120 can be moved into the outputting mechanism 114 and then out of the outputting mechanism 114 through the outlet 124. An example of a suitable outputting mechanism 114 is a mechanism for dispensing droplets of a liquid such as a print head nozzle (e.g., an inkjet print head nozzle). Other examples are illustrated in the drawings and discussed below. The medium 122 can comprise any liquid including, for example, water, oil, or the like.

The base 102 can comprise one or more substrates. As shown, the base 102 can comprise an upper surface 104, a lower surface 106, and an output passage 116 in the base 102. The base 102 can function as a platform on which the processing mechanism 110 and the outputting mechanism 114 are disposed. In some embodiments, the upper surface 104 can be part of the processing mechanism 110. For example, the processing mechanism 110 can manipulate micro-objects 120 on the upper surface 104 of the base 102. As noted, however, the processing mechanism 110 can be disposed on the upper surface 104 of the base 102, and the medium 122 can be inside the processing mechanism 110. In such embodiments, the processing mechanism 110 can manipulate micro-objects 120 on an inner surface of the processing mechanism 110 on which the medium 122 is disposed.

In some embodiments, the base 102 can comprise a single substrate (e.g., a silicon substrate) on which the processing mechanism 110 and the outputting mechanism 114 are disposed. In other embodiments, the base 102 can comprise multiple substrates. For example, in some embodiments, the processing mechanism 110 can be disposed on a first substrate, and the outputting mechanism 114 can be disposed on a second substrate. The first substrate and the second substrate can be attached to each other, and/or the processing mechanism 110 and the outputting mechanism 114 can be connected.

The processing mechanism 110 can comprise one or more micro-fluidic circuit elements for processing micro-objects 120 suspended in the liquid medium 122. Examples of such micro-fluidic circuit elements include micro-fluidic channels, chambers, valves, pumps, or the like. Other examples of such micro-fluidic circuit elements include devices for creating electrokinetic forces on micro-objects 120 in the medium 122 and thereby selecting and/or moving the micro-objects 120. Such devices (not shown) can include devices for creating dielectrophoresis (DEP) forces on selected ones of the micro-objects 120 to select and/or move the micro-objects 120. For example, the processing mechanism 110 can include one or more optical (e.g., laser) tweezers devices and/or one or more optoelectronic tweezers (OET) devices (e.g., as disclosed in U.S. Pat. No. 7,612,355, which is incorporated by reference herein in its entirety). As yet another example, the processing mechanism 110 can include one or more devices (not shown) for moving droplets of the medium 122. Such devices (not shown) can include electrowetting devices such as optoelectronic wetting (OEW) devices (e.g., as disclosed in U.S. Pat. No. 6,958,132, which is incorporated by reference herein in its entirety). Thus, the processing mechanism 110 can comprise any device for processing (as that term is defined above) one or more micro-objects 120 including without limitation a device for creating dielectrophoresis (DEP) forces on selected ones of the micro-objects 120 to select and/or move the micro-objects 120. An example is an OET device. Other examples of the processing mechanism 110 include an OEW device.

As shown, the processing mechanism 110 can include one or more inlets 108 through which the medium 122 with micro-objects 120 can be input into the processing mechanism 110. An inlet 108 can be, for example, an input port, an opening, a valve, or the like. The processing mechanism 110 can also include one or more outlets 124 through which the medium 122 with or without micro-objects 120 can be removed from the processing mechanism 110. An outlet 124 can be, for example, an output port, an opening, a valve, or the like.

As shown in FIGS. 1B and 1C, the outputting mechanism 114 can be configured to output (e.g., express) a droplet 126 of the medium 122 containing one or more of the micro-object(s) 120′ through the output passage 116 in the base 102. As shown in FIGS. 1A-1C, the outputting mechanism 114 and the output passage 116 can be aligned on an axis A, and the droplet 126 can be output through the output passage 116 generally in the direction of the axis A. Although the axis A is shown as perpendicular to the plane of a surface (e.g., the upper surface 104 of the base 102 or an inner surface (not shown) of the processing mechanism 110) on which the medium 122 is disposed, the axis A can be in any direction. For example, the axis A can be at least ten, twenty, thirty, forty, fifty, sixty, seventy, eighty, or more degrees from the plane of the surface on which the medium 122 is disposed. In some embodiments, the axis A can be substantially perpendicular to that plane as illustrated in FIGS. 1A-1C.

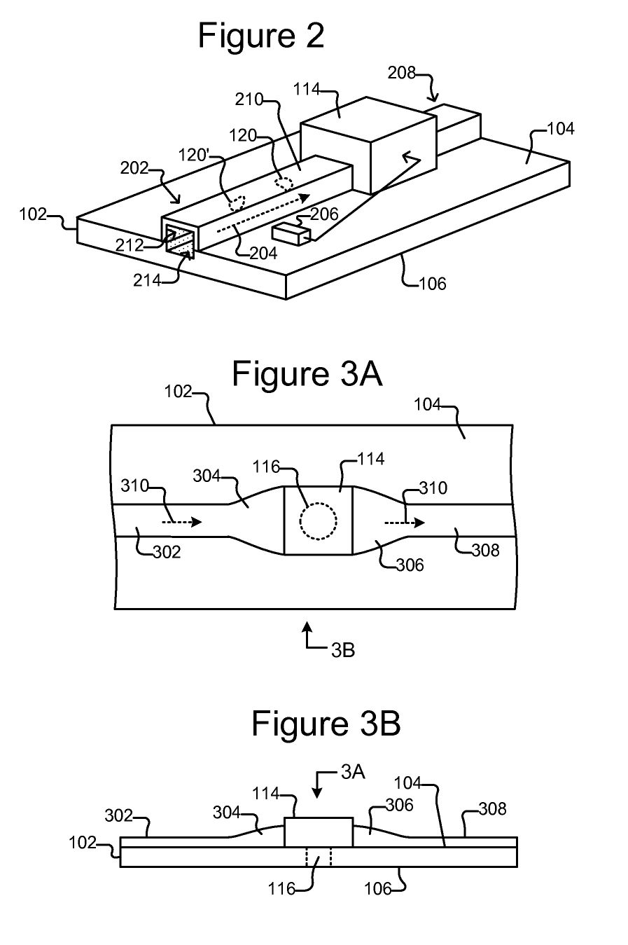

FIGS. 2-6 illustrate specific examples of the processing mechanism 110 according to some embodiments of the invention. The examples illustrated in FIGS. 2-6 can thus replace all or part of the processing mechanism 110 in FIGS. 1A-1C. Moreover, any of the structures illustrated in FIGS. 2-6, including any variations or alternatives discussed herein, are structures for processing micro-objects in a liquid medium substantially in a plane or in a liquid medium (e.g., 122) disposed on a surface of a substrate (e.g., the upper surface 104 of the base 102) or a surface inside the processing mechanism 110.

Turning first to FIG. 2, that figure illustrates a partial perspective view in which the processing mechanism 110 of FIGS. 1A-1C can comprise a micro-fluidic channel 202 for delivering micro-objects 120 to the outputting mechanism 114. A flow 204 of the medium 122 in the channel 202 can move micro-objects 120 toward and into the outputting mechanism 114. As shown, an output channel 208 can be provided from the outputting mechanism 114. As also shown, the channel 202 can comprise cavities 212, 214 in both a housing 210 and the base 102. The channel 208 can similarly be configured. Alternatively, one or both of the channels 202, 208 can comprise a cavity in only the housing 210 or the base 102. Rather than being physical channels, one or both of the channels 202, 208 can be a virtual channel selectively formed on the upper surface 104 of the base 102 (e.g., using OET technology) as will be discussed below.

As shown, in some embodiments, a sensor 206 can detect a position of a micro-object (e.g., micro-object 120′ in FIG. 2) in the channel 202. A signal from the sensor 206 can be used to automatically trigger the outputting mechanism 114, which can be timed to the arrival of the micro-object 120′ per the rate of the flow 204 in the outputting mechanism 114. In other embodiments, however, a sensor 206 is not included, and other mechanisms can trigger the outputting mechanism 114. In some embodiments, there can be more than one sensor 206.

FIGS. 3A and 3B illustrate another example of a micro-fluidic channel 302 for delivering micro-objects 120 to the outputting mechanism 114. The micro-fluidic channel 302 is thus another example of the processing mechanism 110 of FIGS. 1A-1C.

Similar to the channel 202 of FIG. 2, a flow 310 of the medium 122 in the channel 302 can move micro-objects 120 toward and into the outputting mechanism 114, and an output channel 308 can be provided from the outputting mechanism 114. Unlike the channels 202, 208, however, the channel 302 can have a widening portion 304 adjacent the outputting mechanism 114. As shown in FIGS. 3A and 3B, the widening portion 304 can widen in dimensions that are parallel and perpendicular to the upper surface 104 of the base 102. Alternatively, the widening portion 304 can widen only in dimensions that are parallel or perpendicular to the upper surface 104. Regardless, the widening portion 304 can slow the flow of the liquid medium 122 into the outputting mechanism, which can facilitate stopping micro-objects 120 in the outputting mechanism 114, allowing the outputting mechanism 114 to output the micro-objects 120. For example, the rate of the flow 310 can be sufficiently fast so that the micro-objects 120 generally do not settle to the bottom of the channel 302 or became attached to (e.g., by surface tension or other fluidic forces) to sidewalls of the channel 302. Continuing with this example, the widening portion 304 can be sized to slow the flow in the outputting mechanism 114 for at least some of the micro-objects 120 to tend to settle towards the bottom of the outputting mechanism 114. As also shown in FIGS. 3A and 3B, the channel 308 can include a narrowing portion 306 adjacent the outputting mechanism 114, which can increase the rate of the flow 310 of the liquid medium 122 in the channel 308.

Other than the widening portion 304 and the narrowing portion 306, the channels 302, 308 can be generally like the channels 202, 208 as discussed above. The sizes, shapes, and dimensions of the widening portion 304 and the narrowing portion 306 shown in FIGS. 3A and 3B are examples only, and the widening portion 304 and narrowing portion 306 can have other sizes, shapes, and dimensions than illustrated. Moreover, the channels 302, 308 can be physical or virtual generally as discussed above with respect to channels 202, 208. Any channel disclosed or discussed herein can have a widening portion like 304 or a narrowing portion like 306.

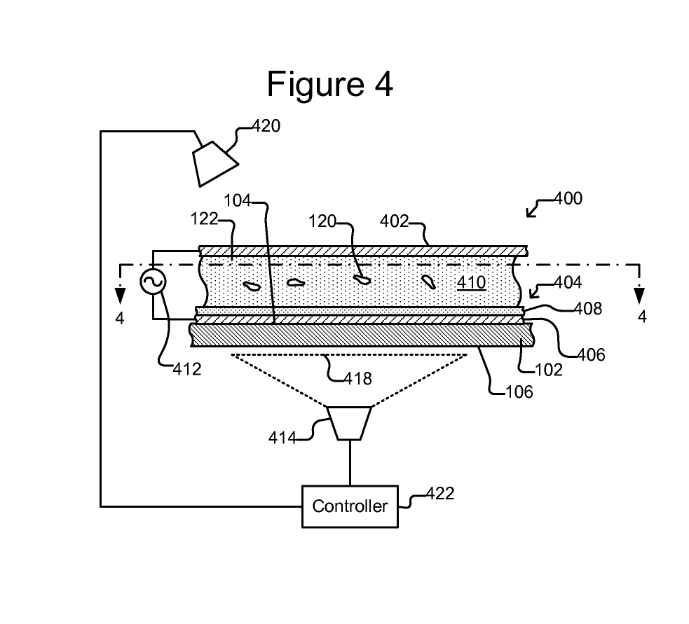

FIG. 4 illustrates another example of the processing mechanism 110 of FIGS. 1A-1C. In the illustrated example, the processing mechanism 110 includes an OET apparatus 400, which as shown, can be disposed on the base 102.

As shown in FIG. 4, the OET apparatus 400 can comprise an upper electrode 402, a wall 404, and a chamber 410 disposed between the upper electrode 402 and the wall 404. The wall 404 can comprise a photoconductive layer 408 and a lower electrode 406. The medium 122 in which the micro-objects 120 are suspended can be in the chamber 410.

As shown, a biasing voltage 412 can be applied to the upper electrode 402 and the lower electrode 406. As is known, light projected onto an area of the photoconductive layer 408 changes the electric field between the upper electrode 402 and the lower electrode 406 in the vicinity of the illuminated area of the photoconductive layer 408. As is also known, depending on the biasing voltage 412, this can attract or repel one or more of the micro-objects 120. A “virtual electrode” that attracts/repels a micro-object 120 can thus be created at any area or areas on the photoconductive material by illuminating the area or areas.

As shown in FIG. 4, the OET apparatus 400 can comprise a light source 414 that can project a light pattern 418 onto the photoconductive layer 408 to selectively illuminate any area or areas of the photoconductive layer 408 and thus create virtual electrodes in any desired pattern on the photoconductive layer 408. The OET apparatus 400 can also include an imaging device 420 (e.g., a camera or other vision device) to monitor the micro-objects 120, and a controller 422 for controlling the light source 414. The upper electrode 402 and/or wall 404 can be transparent.

The configuration of the OET device 400 illustrated in FIG. 4 is an example only. For example, the upper electrode 402 can be part of a wall similar to wall 404. As another example, light source 414 can direct the light pattern 418 from above the upper electrode 402 through the upper electrode 402 and the chamber 410 onto the photoconductive layer 408. These and other variations and modifications are possible.

As noted above, the channels 202, 208 of FIG. 2 and/or the channels 302, 308 of FIG. 3 can be physical channels attached to the upper surface 104 of the base 102, virtual channels, or a combination of physical and virtual channels. As virtual channels, channels 202, 208, 302, 308 (or any part of those channels) can comprise a pattern of virtual electrodes created on the photoconductive layer 408 of FIG. 4 as discussed above.

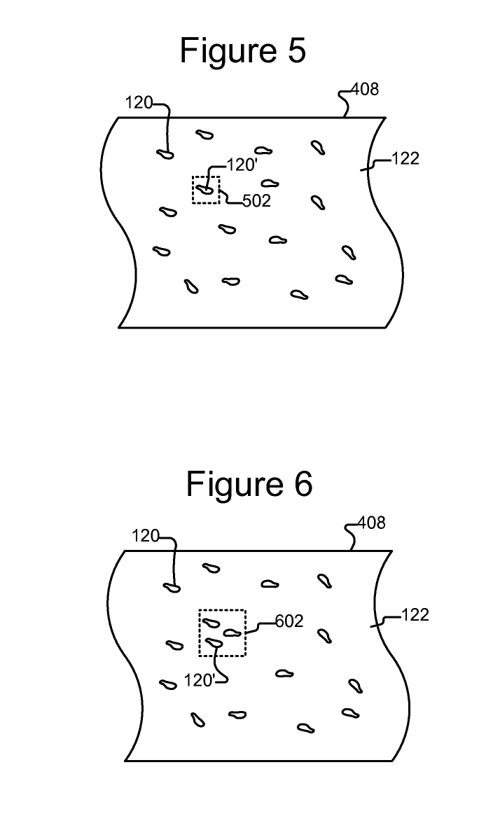

FIG. 5 shows a partial top view of the photoconductive layer 408 of the OET device 400 and illustrates an example in which the OET device 400 can select and move one of the micro-objects 120′. As shown, one of the micro-objects 120′ in the medium 122 can be selected by projecting a light pattern in the form of a light cage 502 onto the photoconductive layer 508 around the micro-object 120′. The biasing voltage 412 (using known techniques) can be set up such that the light cage 502 repels the micro-object 120′. The light cage 502 can then be moved on the photoconductive layer 408 into the outputting mechanism 114 (not shown in FIG. 4). This is one example of a technique for selecting one of the micro-objects 120 and moving the selected micro-object 120′ into the outputting mechanism 114.

FIG. 6 shows the same partial top view of the photoconductive layer 408 of the OET device 400 as FIG. 5 but illustrates an example in which the OET device 400 can select and move a specified number of the micro-objects 120′. As shown, more than one of the micro-objects 120′ in the medium 122 can be selected by projecting a light pattern in the form of a light cage 602 onto the photoconductive layer 408 around the selected micro-objects 120′. The light cage 602 can then be moved on the photoconductive layer 408 into the outputting mechanism 114 (not shown in FIG. 6). This is one example of a technique for selecting a specific number of the micro-objects 120 and moving the selected micro-objects 120′ into the outputting mechanism 114. Although three micro-objects 120′ are selected in FIG. 6, more or fewer can be selected and moved into the outputting mechanism 114. For example, any and every integer number of specific micro-objects 120′ between one and ten, twenty, thirty, or more can be selected by forming the light cage 602 with the OET device 400 of FIG. 4 around the desired specific number of micro-objects 120′ and moving the light cage into the outputting device 114, where the selected micro-objects 120′ can be output in a droplet of medium 122 as discussed above. The OET apparatus 400 can thus be an example of use of dielectrophoresis to trap one or more micro-objects 120.

The channels 204, 208, 302, 308 of FIGS. 2 and 3 and the OET apparatus 400 of FIG. 4 are but examples of the processing mechanism 110 of FIGS. 1A-1C.

For example, the OET apparatus 400 of FIG. 4 can alternatively be an OEW apparatus. For example, the outer surface of the wall 404 in FIG. 4 that directly faces the chamber 410 can be an electrowetting surface, and the light pattern 418 projected onto the photoconductive layer 408 can change the wetting properties of the electrowetting surface. Generally as disclosed in the aforementioned U.S. Pat. No. 6,958,132, a changing light pattern 418 can move droplets of the medium 122 on the electrowetting surface.

As other examples, the processing mechanism 110 can comprise an optical tweezers device for selecting and moving the micro-objects 120 in the medium 122, a fusing device for fusing two or more of the micro-objects 120 together, a device for transfecting the micro-objects 120, a device for growing populations (e.g., colonial populations) of the micro-objects 120, a device for monitoring the micro-objects 120, a device for isolating the micro-objects 120 in holding pens (e.g., virtual, light-created holding pens or physical holding pens).

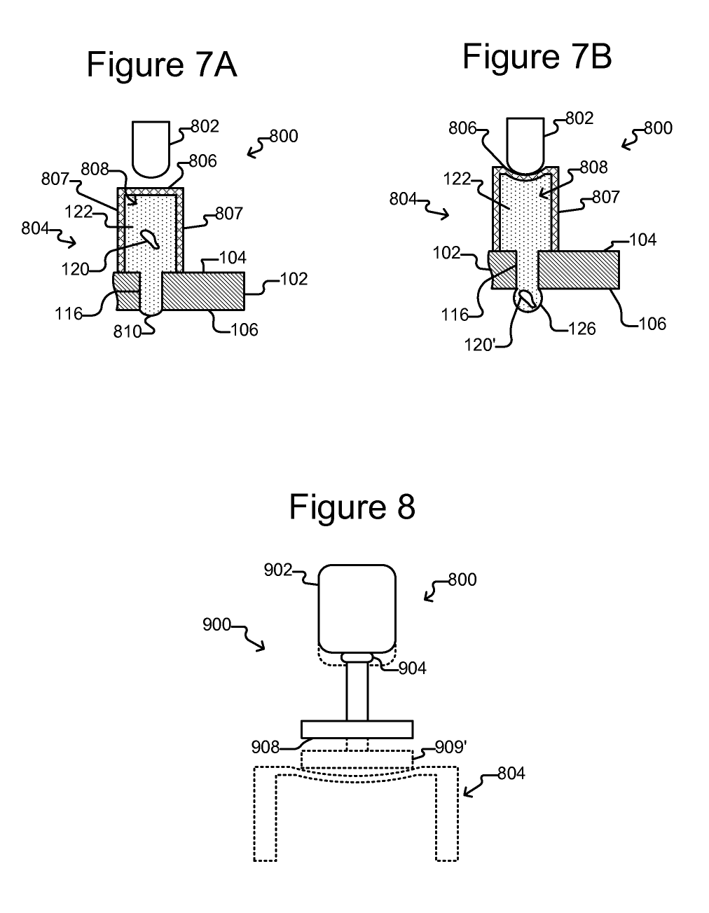

Some examples of the processing mechanism 110 of FIGS. 1A-1C have thus been provided and discussed above. FIGS. 7A and 7B illustrate a generic example of the outputting mechanism 114 of FIGS. 1A-1C according to some embodiments of the invention. The outputting mechanism 800 in FIGS. 7A and 7B can thus replace the outputting mechanism 114 throughout the drawings. Moreover, the outputting mechanism 800, including any variations or alternatives (e.g., inkjet devices) discussed herein, is structure for outputting micro-object(s) 120 in a droplet of medium 122 in a direction that is out of the plane in which the micro-object(s) 120 were processed, which can be the plane of a surface (e.g., the upper surface 104 or an inner surface of the processing mechanism 110) on which the medium 122 is disposed.

In the example shown in FIG. 7A, the outputting mechanism 800 can comprise a striking mechanism 802 and an expressing mechanism 804. The expressing mechanism 804 can comprise an at least partially flexible structure 806 that, with the base 102, defines a reservoir 808 that holds a quantity of the medium 122 in which can be suspended one or more of the micro-objects 120. For example, an upper wall of the structure 806 can be flexible, and sidewalls of the structure 806 can be flexible. As shown in FIG. 7A, the reservoir 808 can be adjacent the output passage 116 in the base 102, and the reservoir 808 and the output passage 116 in the substrate 116 can be sized and positioned such that the medium 122 forms a meniscus 810 at the output passage 116.

As shown in FIG. 7B, per the definition of “strike” above, the striking mechanism 802 can strike (with a motion that results in sudden and abrupt contact with) the expressing mechanism 804 and with sufficient momentum to cause a sudden and abrupt force on the expressing mechanism 804 sufficient to deform a flexible portion of the structure 806 and thereby decrease the volume of the reservoir 808 sufficiently to express (e.g., squeeze) a droplet 126 of the medium 122 out of the output passage 116. As shown, the droplet 126 can contain one or more of the micro-objects 120′. The flexible portion of the structure 806 can comprise a compressible material (e.g. rubber, plastic, an elastomer, polydimethylsiloxane (“PDMS”), or the like). A striking action that is sudden or abrupt can readily provide sufficient force to overcome surface tension that otherwise keeps the medium 122 from flowing from the reservoir 108 and out of the output passage 116. In some embodiments, a striking action can be more efficient than a more gradual pressing or squeezing of the flexible portion of the structure 806 in expressing a droplet 126.

To facilitate separation of the droplet 126 from the output passage 116, the striking mechanism 802 can strike the expressing mechanism 804 with a rapid motion to generate sufficient momentum in the droplet 126 to overcome surface tensions and hydrodynamic forces and thereby separate the droplet 126 from the output passage 116. The striking mechanism 802 can thus be configured to move with at least a speed that is sufficient to generate the necessary droplet 126 momentum. This speed can be constant throughout the movement of the striking mechanism 802 or varied. For example, the speed of the striking mechanism 802 can initially be a first, slower speed to avoid excessive disturbance within the medium 122. This speed can later be increased to a second, faster speed to generate sufficient momentum for the droplet 126 to separate from the output passage 116. In some embodiments, the first, slower speed can be imparted to the striking mechanism 802 prior to striking the expressing mechanism 804 and the second, faster speed can be imparted to the striking mechanism 802 after striking the expressing mechanism 804.

As another example of a technique for separating the droplet 126 from the output passage 116, a droplet 126 expressed from but still adhered to the output passage 116, can be brought into contact with a structure (not shown) such as a device for receiving the droplet 126. Examples of such a structure (not shown) include a plate, a holding device, or the like. Surface wetting by the droplet 126 of the structure (not shown) can separate the droplet 126 from the output passage 116.

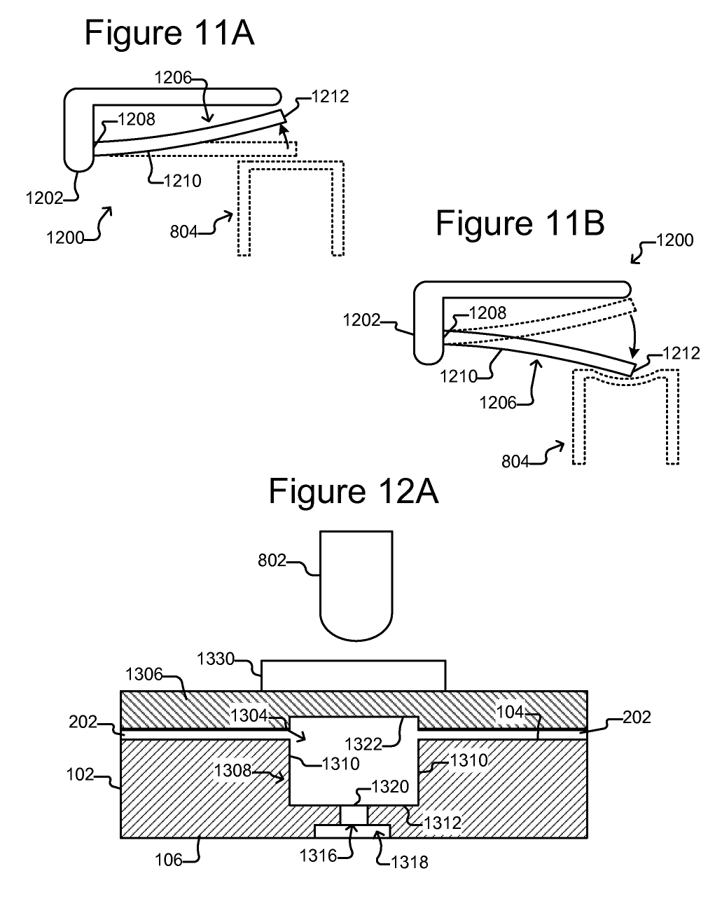

FIGS. 8-11B illustrate examples of the striking mechanism 802 of FIG. 7A. As will be seen, FIGS. 8-10 illustrate examples in which the striking mechanism 900, 1100 comprises an actuator 902 and a hammer 906, and FIGS. 11A and 11B illustrate an example in which the striking mechanism 1200 comprises an actuator 1202 and a spring 1206. The striking mechanisms 900, 1100, 1200 are examples of the striking mechanism 802 and the striking mechanism 802 in any of the Figures can be configured as striking mechanisms 900, 1100, 1200.

As shown in FIG. 8, the striking mechanism 900 can comprise an actuator 902 and a hammer 906. A joint 904 (e.g., solder, adhesive, a weld, or the like) can attach the hammer 906 to the actuator 902.

The actuator 902 can be any mechanism for moving the hammer 906 to strike and thus deform (e.g., compress) the structure 806 of the expressing mechanism 804 as shown in FIG. 8. For example, the actuator 902 can comprise a piezoelectric material (e.g., a piezoelectric element or stack comprising lead zirconate titanate (PZT), piezocrystal, piezopolymer, or the like) that expands, as shown in FIG. 2, in response to a change in a voltage applied to the piezoelectric material. The expansion of the piezoelectric material can move the hammer 906 into contact with the structure 806, deforming the structure 806. Alternatively, the actuator 902 can comprise mechanisms other than a piezoelectric material for driving the hammer 906. Examples of alternative mechanisms for the actuator 902 include a voice coil and the like.

In some embodiments, the hammer 906 can be fabricated separately and then attached by the joint 904 to the actuator 902. Alternatively, the hammer 906 can be fabricated on the actuator 902. Regardless, the hammer 906 can be made using lithographic techniques, micromachining, molding, or the like.

The hammer 906 can comprise a head 908 that contacts and deforms the structure 806 as the actuator 902 moves the hammer 906. The head 908 can have any of a variety of shapes and surface configurations. For example, the head 908 can be flat (as shown in FIG. 8), angled, or curved and can be circular, square, rectangular, or the like.

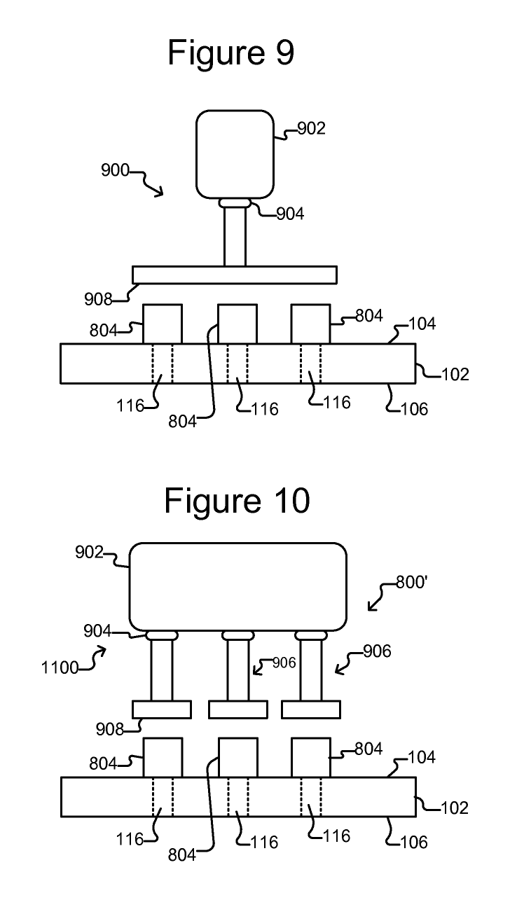

One hammer 906 attached to one actuator 902 to contact one expressing mechanism 804 as illustrated in FIG. 8 is but an example. FIG. 9 illustrates another example in which the hammer 906 of the striking mechanism 900 is sized and configured to contact and deform the flexible portions of the structures 806 of more than one expressing mechanism 804. In another example, FIG. 10 illustrates a striking mechanism 1000 in which the actuator 902 can drive multiple hammers 906 to contact and deform the flexible portions of the structures 806 of multiple expressing mechanisms 804.

As shown in FIGS. 11A and 11B, a striking mechanism 1200 can alternatively comprise an actuator 1202 and a spring 1206. As shown, the spring 1206 can comprise a beam 1210, which can have a fixed end 1208 and a free end 1212. As shown in FIG. 11A, the actuator 1202 can move (e.g., bend) the free end 1212 of the beam 1210 away from the expressing mechanism 804, which can effectively compress the spring 1206. As illustrated in FIG. 11B, the actuator 1202 can then release the free end 1212, and the spring forces in the beam 1210 can cause the beam 1210 to strike and thereby deform (e.g., compress) the expressing mechanism 804 as shown. The spring 1206 can be made to strike the expressing mechanism 804 with sufficient velocity or force to overcome surface tension and other such forces to express the droplet 126 (see FIGS. 7A and 7B).

The actuator 1202 can be any mechanism for moving the free end 1212 of the beam 1210 away from the expressing mechanism 804. For example, the actuator 1202 can be a motor, a mechanical actuator, an electromagnet, a piezoelectric element, or the like. The beam 1210 can comprise a resilient material. Although shown as a beam 1210, the spring 1206 can be other types of springs.

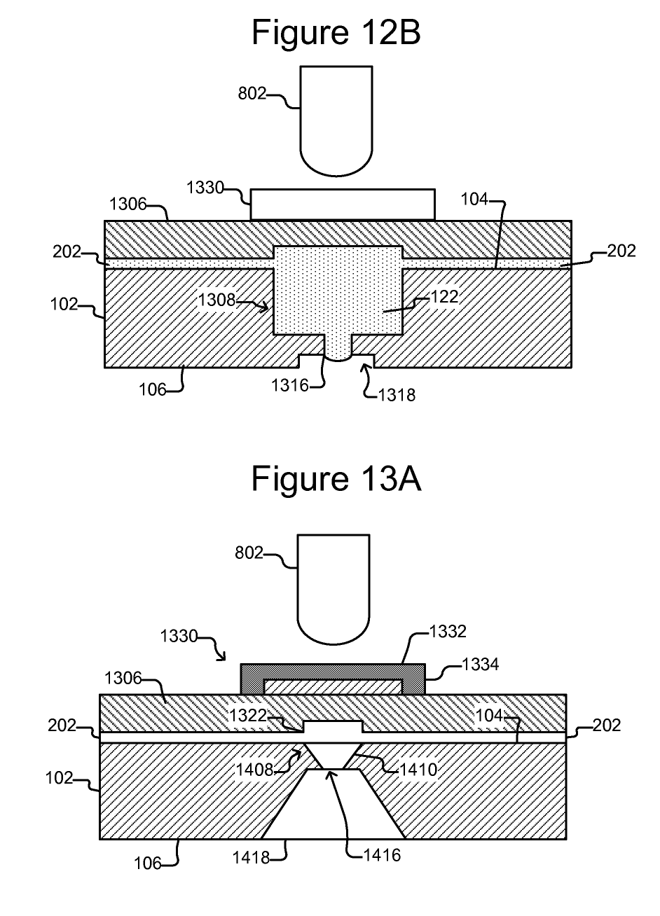

As noted, FIGS. 8-11B are examples of the striking mechanism 802 of FIG. 7A. Examples of the expressing mechanism 804 of FIG. 7A and the output passage 116 are shown in FIGS. 12A-21. The expressing mechanism 804 and/or output passage 116 in any of the Figures can thus be configured as shown in any of FIGS. 12A-21.

FIGS. 12A and 12B illustrate an example of the expressing mechanism 804 and output passage 116. As shown in FIG. 12A, the expressing mechanism can comprise a flexible structure 1306 disposed on the surface 104 of the base 102. The flexible structure 1306 can comprise a compressible material (e.g. rubber, plastic, an elastomer, polydimethylsiloxane (“PDMS”), or the like). As also shown, in some embodiments, a cap structure 1330 can be disposed on the flexible structure 1306, and the striking mechanism 802 can be positioned and configured to strike the cap structure 1330 rather than striking the flexible structure 1306 directly. The cap structure 1330 can comprise flexible and rigid elements and can be configured to transfer at least part of the force of a strike by the striking mechanism 804 to the flexible structure 1306. In any embodiment disclosed herein, however, there need not be a cap structure 1330, and the striking mechanism 804 can alternatively strike, for example, the flexible structure (e.g., 1306) directly.

The flexible structure 1306 and the base 102 can define a reservoir 1308. As shown, the flexible substrate 1306 can define an upper wall of the reservoir 1308, and a cavity in the base 102 can define sidewalls 1310 and a bottom wall 1312 of the reservoir 1308. As shown, the reservoir 1308 can also include a notch 1322 in the flexible structure 1306. As also shown, the flexible structure 1306 and the base 102 can define channels 202 into and out of the reservoir 1308. The base 102 can also include an output passage 1316 (which can be an example of the output passage 116 in other Figures) from the bottom wall 1312 of the reservoir 1308 to an outlet space 1318. The reservoir 1316 can be significantly larger than the output passage 1316. For example, an opening 1320 of the output passage 1316 at the bottom wall 1312 can be significantly smaller than the bottom wall 1312. In some embodiments, the area of the opening 1320 can be two, three, four, five, or more times larger than the area of the bottom wall 1312.

FIG. 12B illustrates medium 122 in the channels 202, reservoir 1308, and output passage 1316. Generally consistent with discussions above, the force of the striking mechanism 802 striking the cap structure 1330 (or if there is no cap structure, the flexible structure 1306 adjacent (e.g., immediately above) the reservoir 1308) can compress the flexible structure 1306 and express a droplet (not shown) out of the output passage 1316. That the reservoir 1308 is significantly larger than the output passage 1316 can advantageously reduce the striking force required of the striking mechanism 802 to express a droplet out of the output passage 1316.

Thus, in FIGS. 12A and 12B, a combination of one or more of the cap structure 1330, the flexible structure 1306, the reservoir 1308, and the passage 1316 can be an example of the expressing mechanism 804.

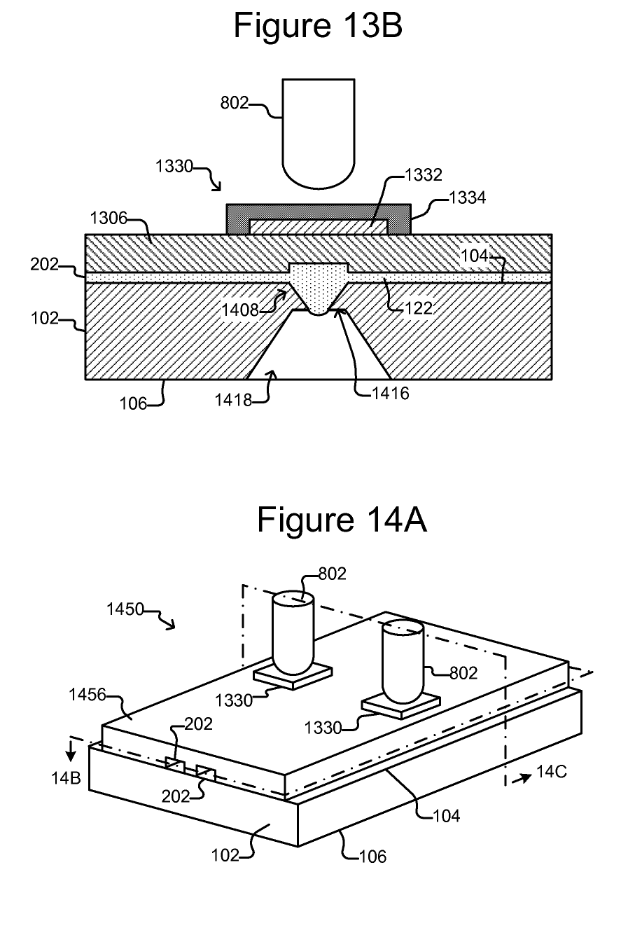

The configuration shown in FIGS. 13A and 13B is an example, and variations are possible. For example, there need not be a notch 1322 in the flexible structure 1306, or the notch 1322 can have a different shape. As another example, there need not be an outlet space 1318, or the outlet space 1318 can have a different shape. As yet another example, the cavity in the base 102 that defines the sidewalls 1310 and bottom wall 1320 can be a different size or shape.

FIGS. 13A and 13B illustrate another example of the expressing mechanism 804 of FIG. 7A and the output passage 116, and FIGS. 13A and 13B also illustrate an example of the cap structure 1330, which as shown, can comprise a flexible material 1332 covered by a rigid cap 1334. As shown in FIG. 13A, the expressing mechanism can comprise the flexible structure 1306 disposed on the surface 104 of the base 102, and the flexible structure 1306 and the base 102 can define channels 202 to and from a reservoir 1408 generally as discussed above. As shown in FIG. 13A, however, the cavity in the base 102 can have sloped sidewalls 1410, which can help guide a micro-object (not shown but like micro-object 120) towards an output passage 1416, which can be an example of the output passage 116 in other Figures. As also shown in FIG. 13A, the base 102 can include an outlet space 1418 with sidewalls that slope away from the output passage 1416.

FIG. 13B illustrates medium 122 in the channels 202, reservoir 1408, and output passage 1416. Generally consistent with discussions above, the force of the striking mechanism 802 striking the cap 1334 (or if there is no cap 1334 and flexible material 1332, striking the flexible structure 1306 adjacent (e.g., immediately above) the reservoir 1408) can compress the flexible structure 1306 and express a droplet (not shown) out of the output passage 1416.

The configuration shown in FIGS. 13A and 13B is an example, and variations are possible. For example, there need not be a notch 1322 in the flexible structure 1306, or the notch 1322 can have a different shape. As another example, there need not be an outlet space 1418, or the outlet space 1418 can have a different shape. As yet another example, the cavity in the base 102 that defines the sloped sidewalls 1410 can be a different size or shape.

In FIGS. 13A and 13B, a combination of one or more of the cap structure 1330, the flexible structure 1306, the reservoir 1408, and the passage 1416 can be an example of the expressing mechanism 804.

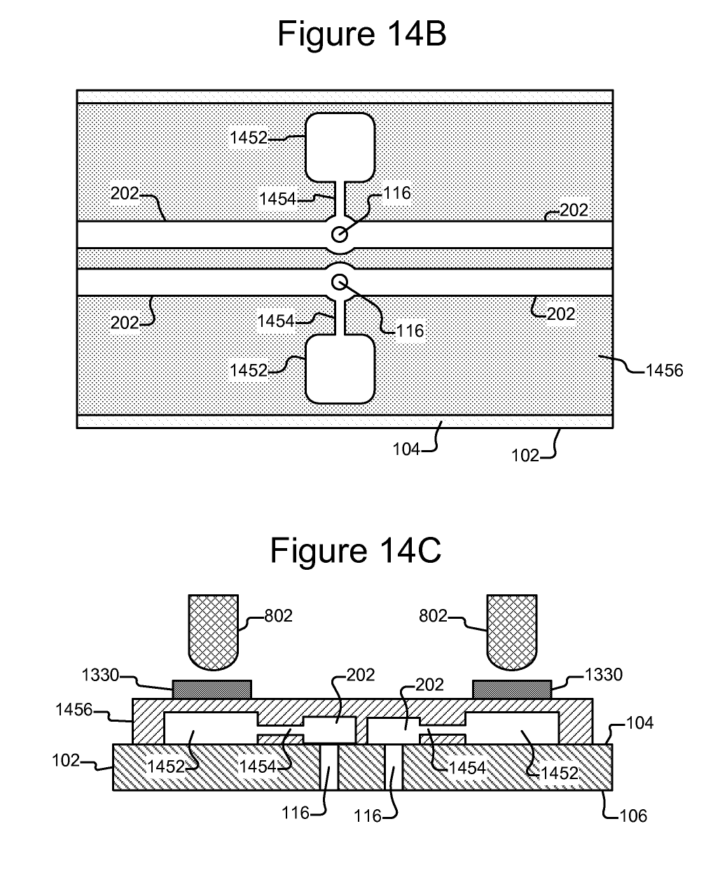

FIGS. 14A-14C illustrate an example of a processing/outputting microfluidic device 1450 in which reservoirs 1452 are spaced a distance (e.g., laterally) from corresponding output passages 116 in the base 102. As shown, the device 1450 can comprise a flexible structure 1456 disposed on the base 102. The flexible structure 1456 can be generally similar to flexible structure 1306 and can comprise the same materials as discussed above with respect to flexible structure 1306. Multiple channels 202 can be defined in the flexible structure 1456, and such channel 202 can lead to and away from an output passage 116 as shown. As also shown, reservoirs 1452 (which can be generally similar to any of the reservoirs discussed above) defined in the flexible structure 1456 can be disposed a distance away from respective output passages 116, and fluidic feeds 1454 (e.g., channels) can fluidically connect each reservoir 1452 to one of the channels 202 and thus an output passage 116. As a striking mechanism 802 strikes a cap structure 1330 adjacent (e.g., above) a reservoir 1452, medium 122 in the reservoir can be expressed through the feed 1454 into a channel 202 adjacent an output passage 116 expressing a droplet through the output passage 116 generally as discussed above. By disposing the reservoirs 1452 away from the output passages 116 to which the feeds 1454 connect, the output passages 116 can be disposed closer together than the size of the reservoir 1452 and/or striking mechanism 802 might otherwise allow. In addition, because the space above the output passages 116 is not occupied by reservoirs 1452 or striking mechanisms 802, portions of the channels 202 adjacent the output passages 116 can be observed or monitored.

In FIGS. 14A-14C, a combination of one or more of a cap structure 1330, the flexible structure 1456, a reservoir 1452, a fluidic feed 1454, and an output passage 116 can be an example of the expressing mechanism 804.

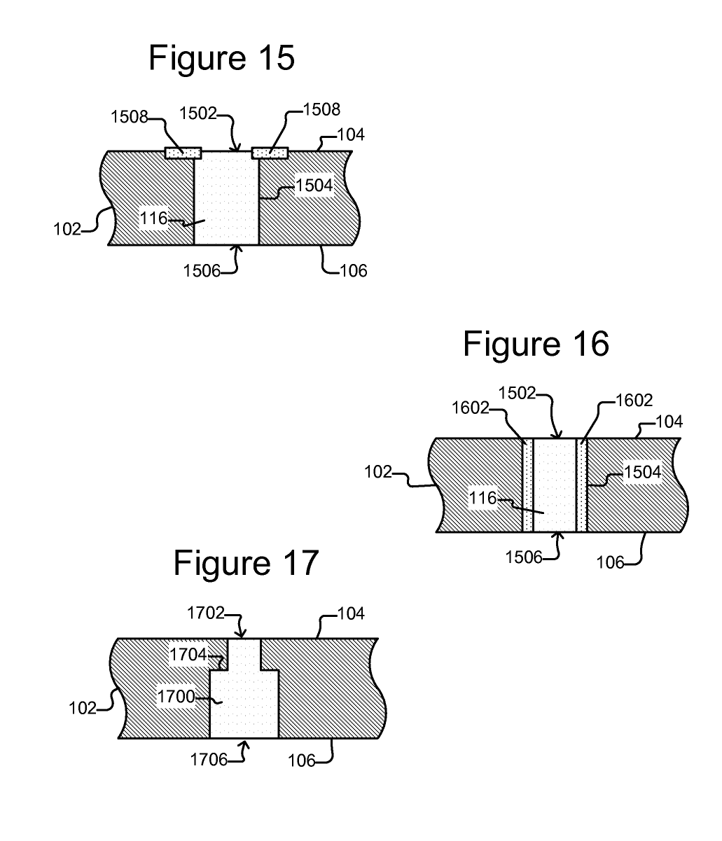

FIGS. 15-17 illustrate additional example configurations of the output passage 116 in the base 102. Any of the output passages 116 (including output passages 1316 and 1416 in FIGS. 12A, 12B, 13A, and 13B) can be configured as illustrated in FIGS. 15-17.

As shown in FIG. 15, the output passage 116 can comprise an upper opening 1502 in the upper surface 104 of the base 102 and a lower opening 1506 in the lower surface 106 of the base 102. Sidewalls of the output passage 116 are labeled 1504. As also shown, hydrophobic material 1508 can be disposed on the upper surface 104 around the upper opening 1502 of the output passage 116. The hydrophobic material 1508 can repel the medium 122, which can impede the medium 122 from entering the output passage 116 until the outputting mechanism 114 is activated to express a droplet 126 (see FIG. 1C). As shown in FIG. 16, hydrophobic material 1602 can alternatively be disposed on the sidewalls 1504 to repel the medium 122 and thereby prevent the medium 122 from entering the output passage 116 until the outputting mechanism 114 is activated to express a droplet 126 (see FIG. 1C).

Alternatively, the material 1508 in FIG. 15 and/or the material 1602 in FIG. 16 can be hydrophilic. In such a case, the material 1508 in FIG. 15 can draw the medium 122 partially into the output passage 116, and the outputting mechanism 114 can then express a droplet 126 of the medium 122 (see also FIG. 1C) out of the lower opening 1506. If material 1602 in FIG. 16 is hydrophilic, the material 1602 can draw the medium 122 into the output passage 116, but the lower edges of the material 1602 can prevent the medium from exiting the lower opening 1606 until the outputting mechanism 114 forces a droplet 126 of the medium 122 out the lower opening 1506 (see also FIG. 1C).

FIG. 17 illustrates an output passage 1700 (which is an example of and can thus replace the output passage 116 in other Figures) that includes a step 1704 between an upper opening 1702 of the output passage 1700 at the upper surface 104 of the base 102 and a lower opening 1706 of the output passage at the lower surface 106 of the base 102. As shown, the lower opening 1706 can be bigger than the upper opening 1702. Alternatively, the upper opening 1702 can be bigger. Rather than having step 1704, the output passage 1700 can alternatively taper from the upper opening 1702 to the lower opening 1006. Although not shown, hydrophobic or hydrophilic material (e.g., like material 1508 or 1602) can be disposed, for example, around the upper opening 1702 and or on sidewalls of the output passage 1706 between the upper opening 1702 and the step 1704.

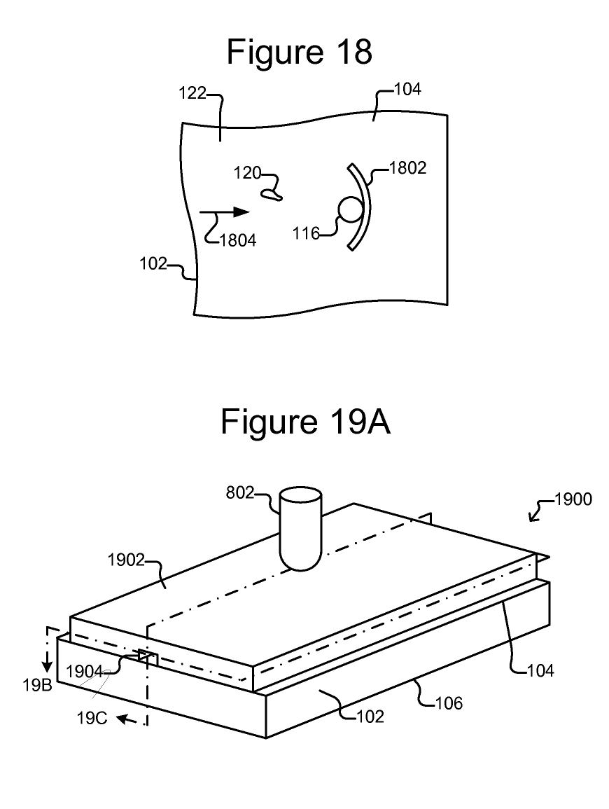

FIG. 18 illustrates an example in which a barrier 1802 is disposed on the upper surface 104 of the base 102 adjacent the output passage 116. The barrier 1802 can be positioned and shaped to guide a micro-object 120 into the output passage 116 as the micro-object 120 is moved to the output passage 116 by, for example, a flow 1804 of the medium 122. The shape and location of the barrier 1802 shown in FIG. 18 are examples, and the barrier 1802 can have other shapes and be in other locations. For example, the barrier 1802 can comprise multiple structures disposed in an arcing pattern partially around the output passage 116 on the upper surface 104 of the base 102.

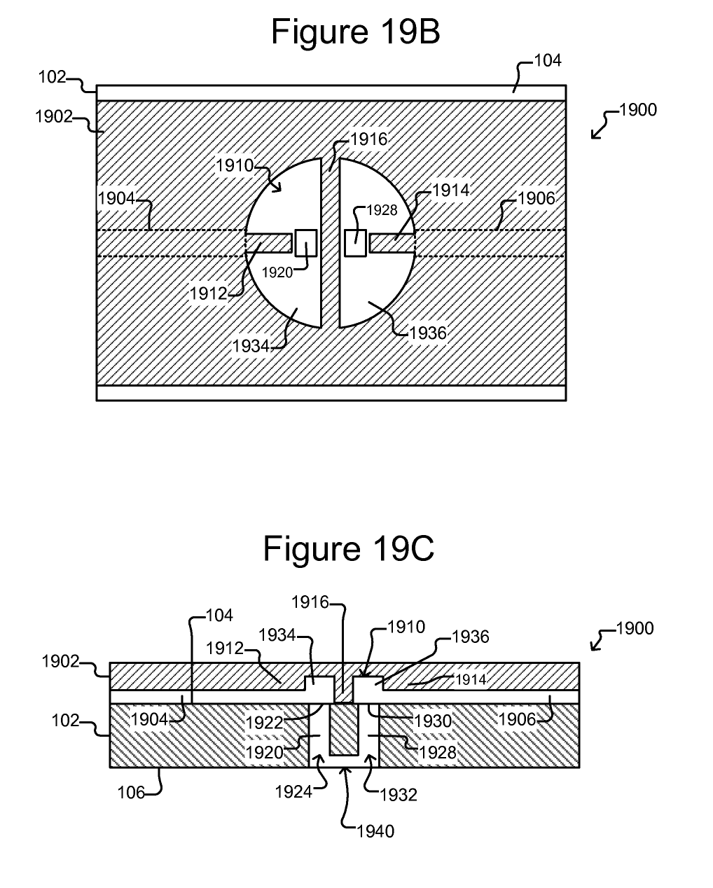

FIGS. 19A-21 illustrate still other example configurations of the expressing mechanism 804 of FIG. 7A and the output passage 116. As shown, the expressing mechanism can comprise a flexible structure 1902, which can be disposed on the surface 104 of the base 102. The flexible structure 1902 can comprise any of the materials discussed above with regard to the flexible structure 1306.

As shown, the flexible structure 1902 and the base 102 can define a reservoir 1910 and channels 1902, 1906 to and from the reservoir 1910. As also shown, there can be a divider 1916, which can be part of the flex structure 1902, that divides the reservoir 1910 into a first portion 1934 and a second portion 1936. There can also be holes 1920, 1928 from the reservoir 1910 through the base 102 to the lower surface 106. A first of the holes 1920 can have an upper opening 1922 at the upper surface 104 of the base 102 and a lower opening 1924 at a common exit space 1940 adjacent the lower surface 106. A second of the holes 1928 can similarly have an upper opening 1930 at the upper surface 104 of the base 102 and a lower opening 1932 at the common exit space 1940 adjacent the lower surface 106. The flex structure 1902 can also comprise extensions 1912 and 1914.

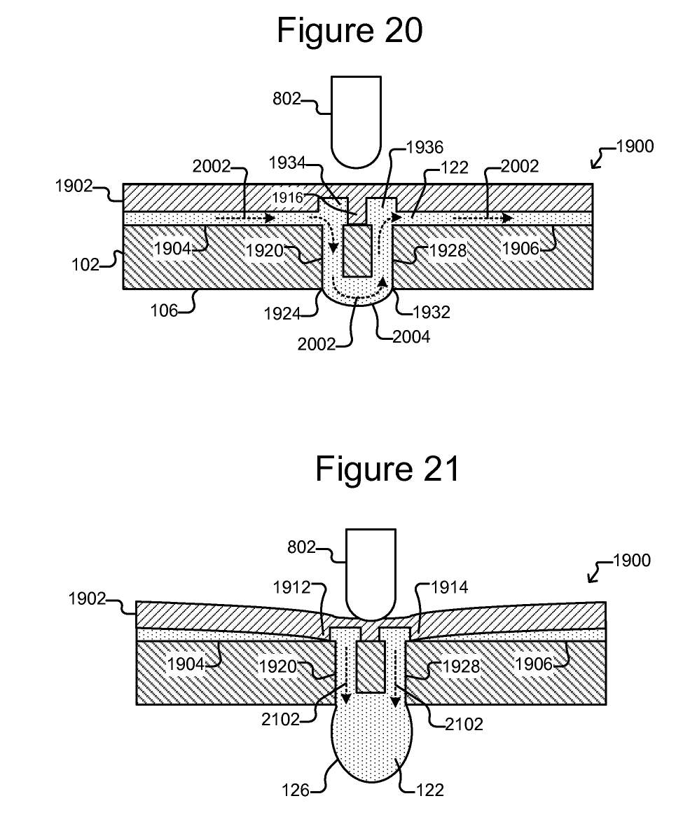

As illustrated in FIG. 20, the medium 122 can flow 2002 through the channel 1904 into and down the first hole 1920, flow 2002 as a meniscus 2004 from the lower opening 1924 of the first hole 1920 to the lower opening 1932 of the second hole 1928, flow through the common space 1940, and flow up the second hole 1928 into and through the channel 1906. Although not shown in FIG. 20, micro-objects 120 can flow 2002 with the medium 122 in the foregoing pattern.

As shown in FIG. 21, the striking mechanism 802 can strike the flexible structure 1902 adjacent (e.g., immediately above) the reservoir 1910 and compress the flexible structure 1902. Alternatively, there can be a cap structure like cap structure 1330 disposed on the flexible structure 1902, and the striking mechanism 802 can strike the cap structure. This can cause the extensions 1912, 1914 to close the channels 1904, 1906, as illustrated in FIG. 21, and flow 2102 medium 122 from the reservoir 1910 down both holes 1920, 1928, expressing a droplet 126. Although not shown, there can be one or more micro-objects 120 in the droplet 126.

In FIGS. 19A-21, a combination of one or more of the flexible structure 1902 (including one or more of the extensions 1912 and 1914 and the divider 1916), the reservoir cavity 1902, the holes 1920 and 1928, and the common space 1940 can be an example of the expressing mechanism 804.

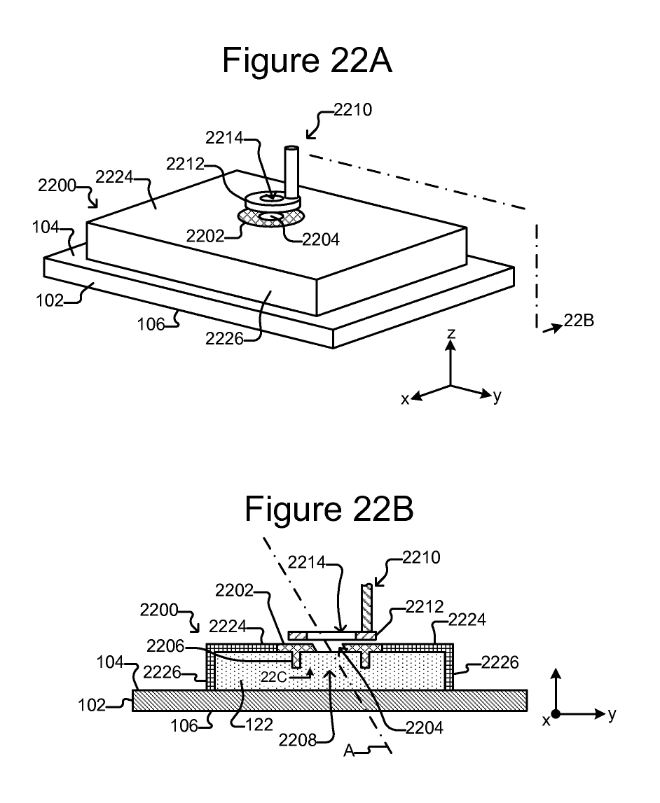

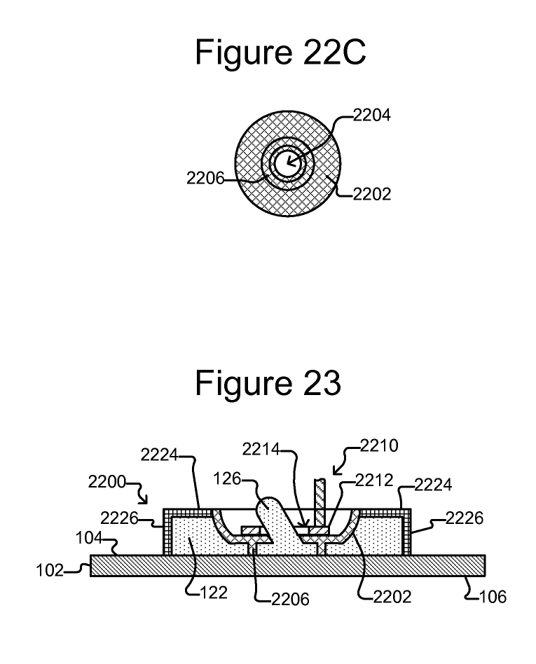

FIGS. 22A-25C illustrate additional examples of configurations or alternative variations of the striking mechanism 802, the expressing mechanism 804, and/or the output passage 116.

FIGS. 22A-22C and 23 illustrate an example in which a droplet 126 can be expressed upward against the force of gravity. As shown, the example can include a striking mechanism that comprises a hammer 2210 that has a head 2212. Although not shown, an actuator like actuator 902, for example, can actuate the hammer 2210, causing the hammer 2210 to strike a flex structure 2202. The expressing mechanism 2200 in FIGS. 22A-22C and 23 comprises rigid side walls 2226, rigid upper walls 2224, and a flexible structure 2202 that, with the base 102, define a reservoir 2208 that can hold medium 122. As shown, there can be an output passage 2204 in the flexible structure 2202 and an output passage 2214 in the head 2212. In addition, the flexible structure 2202 can have flexible sidewalls 2206. The flexible structure 2202 can comprise any of the materials discussed above with regard to the structure 1306

As shown in FIG. 23, the hammer 2210 can be pressed against the flexible structure 2202 such that the sidewalls 2206 that extend from the flexible structure 2202 are compressed against the upper surface 104 of the base 102. As also shown in FIG. 23, this can compress the sidewalls 2206 and express a droplet 126 of the medium 122 from the reservoir 2208 upward against the force of gravity through the output passages 2204, 2214.

In FIGS. 22A-22C and 23, the expressing mechanism 2200 can be an example of the expressing mechanism 804.

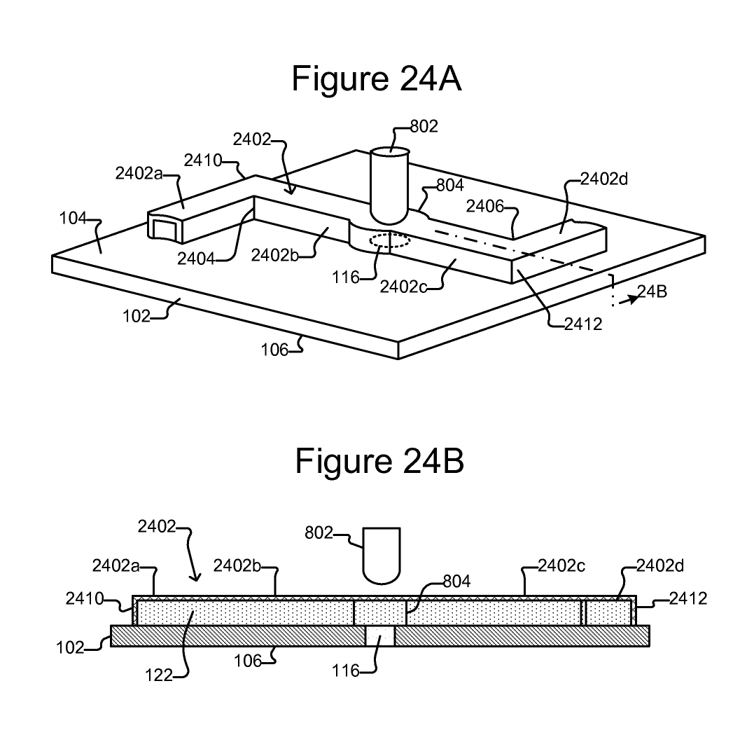

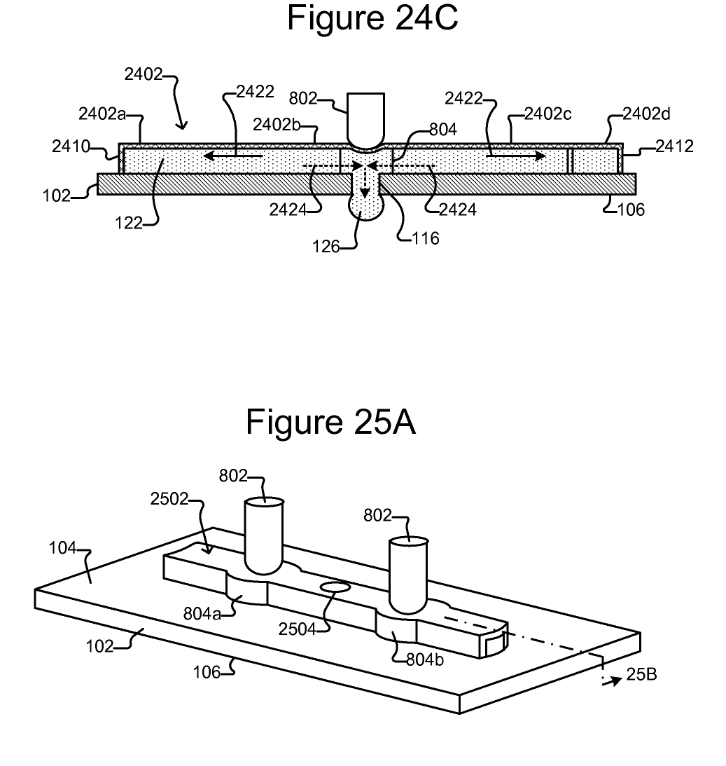

FIGS. 24A-24C illustrate an example in which the expressing mechanism 804 of FIGS. 7A and 7B can be part of a micro-fluidic channel disposed on the base 102. FIGS. 24A-24C illustrate part of a micro-fluidic channel 2402 that can be disposed on the base 102. As shown, the expressing mechanism 804 can be disposed in the channel 2402. In the example shown in FIGS. 24A-24C, the expressing mechanism 804 is located between channel sections labeled 2402b and 2402c. As shown, a bend 2404 in the channel 2402 can be between what are labeled channel sections 2402a and 2402b, and another bend 2406 can be between channel sections 2402c and 2402d.

As discussed above, the expressing mechanism 804 can comprise in whole or in part a flexible material. The rest of the channel 2402 can comprise a rigid material and/or a flexible material. As shown in FIG. 24C, the striking mechanism 802 can strike and thereby compress the expressing mechanism 804 (as discussed above with respect to FIGS. 7A and 7B), which can cause the expressing mechanism 804 to express a droplet 126 of the medium 122 in the channel 2402 through the output passage 116. Alternatively, there can be a cap structure like cap structure 1330 disposed between the striking mechanism 802 and the expressing mechanism 804, and the striking mechanism 802 can strike the cap structure. Regardless, as also shown, compression of the expressing mechanism 804 can cause the medium 122 in the channel 2402 to flow 2422 away from the expressing mechanism 804. Sidewalls 2410 and 2412 of the channel 2402 at the bends 2404 and 2406 can reflect the flow 2424 back toward the expressing mechanism 804. These reflected flows 2424 of the medium 122 can express the droplet 126 through the output passage 116 upward against the force of gravity as shown. The flow resistance in the channel sections 2402b and 2402c (which can be balanced or unbalanced) can be sufficiently large so that the droplet 126 is forced out the hole 116.

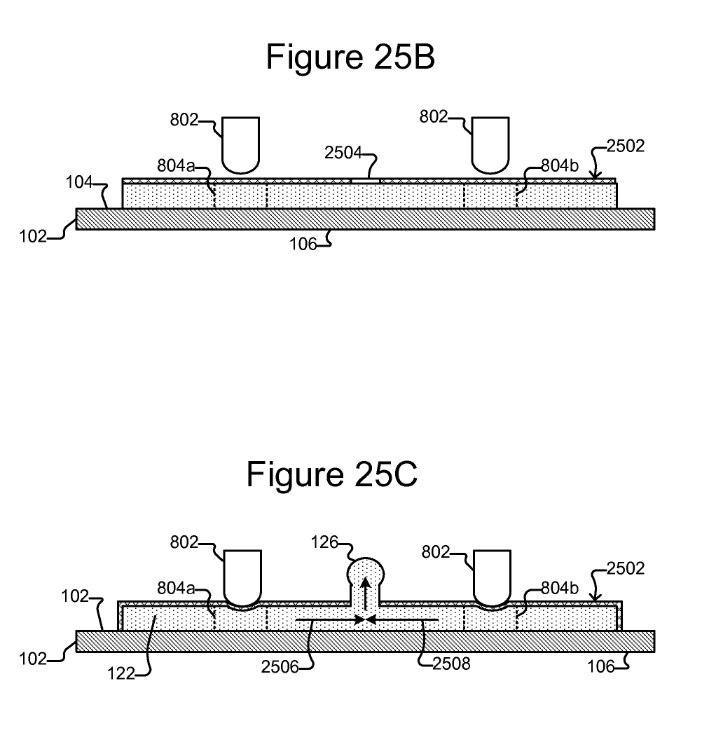

FIGS. 25A-25C illustrate part of a micro-fluidic channel 2502 that can be disposed on the base 102. As shown, expressing mechanisms 804a and 804b (see FIGS. 7A and 7B) can be disposed on either side of an output passage 2504 in the channel 2502. As shown in FIG. 25C, striking mechanisms 802 can strike and thereby compress the expressing mechanisms 804a and 804b, which can cause the expressing mechanisms 804a and 804b to express respective flows 2506 and 2508 of the medium 122 in the channel 2502 toward the output passage 2504. Alternatively, there can be cap structures each like cap structure 1330 disposed between each striking structure 802 and expressing mechanism 804a, 804b, and the striking mechanisms 802 can strike the cap structures. Regardless, these flows 2506 and 2508 of the medium 122 can express the droplet 126 from the output passage 2504, which as shown in FIG. 25C, can express a droplet 126 upward against the force of gravity.

The channel 2502 can comprise a flexible material. Alternatively, the expressing mechanism 804a and 804b can be flexible but other portions of the channel 1902 can be rigid. The output passage 2504 is shown as being in an upper wall of the channel 1902 but can alternatively be in a sidewall of the channel 2502. The output passage 2504 can also alternatively be in the base 102. A chamber (not shown) can be provided in the channel 2502 adjacent the output passage 2504.

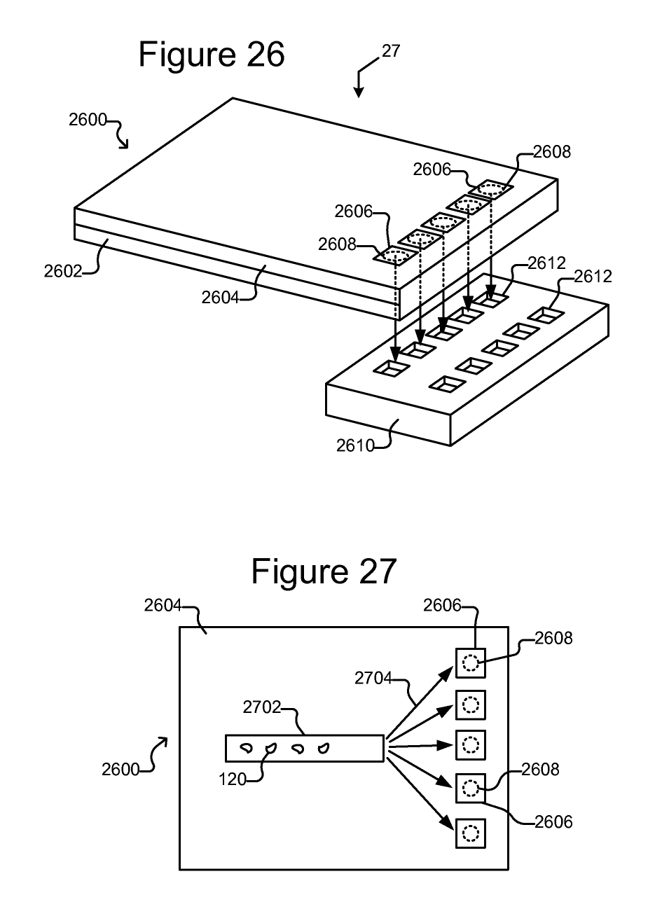

The processing/outputting device 100 of FIGS. 1A-1C can comprise more than one outputting mechanism 114. FIG. 26 illustrates an example of such a processing/outputting device 2600, which can comprise a base 2602, one or more processing mechanisms 2604, and a plurality of outputting mechanisms 2606. The base 2602 can be the same as or similar to the base 102 of FIGS. 1A-1C. The processing mechanism 2604 can likewise be the same as or similar to the processing mechanism 110, and each outputting mechanism 2606 can be the same as or similar to the outputting mechanism 114. That is, each outputting mechanism 2606 can output through an output passage 2608 (which can be like the output passage 116) in the base 2602 one or more selected micro-objects 120 in a droplet 126 of medium 122 generally as illustrated in FIG. 1C. Although one row of outputting mechanisms 2606 is shown, there can be multiple rows. Thus, for example, there can be an array of outputting mechanisms 2606.

The processing/outputting device 2600 can be utilized as follows. Micro-objects 120 can be moved into each of the outputting mechanisms 2606. The output passages 2608 can be aligned with a first row of wells 2612 in a holder 2610. The outputting mechanisms 2606 can simultaneously output the micro-objects 120 through the output passages 2608 into the first row of wells 2612. New micro-objects 120 can then be moved into each of the outputting mechanisms 2606, the output passages 2608 of the device 2600 can be aligned with a second row of the wells 2612, and the outputting mechanisms 2606 can simultaneously output the new micro-objects 120 through the output passages 2606 into the second row of wells 2612 in the holder 2610.

The foregoing is but one example of the device 2600 and how the device 2600 can be utilized, and alternatives are of course possible. For example, the device 1200 can have the same number of rows of outputting mechanisms 2606 as the holder 2610 has rows of wells 2612. As another example, there can be a different number of outputting mechanisms 2608 in a row of outputting mechanisms than the number of wells 2612 in a row of wells. As yet another example, micro-objects 120 need not be outputted simultaneously from the outputting mechanisms 2608. That is, a first outputting mechanism 2606 can be loaded with a micro-object 120, and while the first outputting mechanism 2606 is outputting the micro-object 120 into a well 2612, a second outputting mechanism 2606 can be loaded with another micro-object 120.

FIG. 27 illustrates a configuration of the device 2700 in which micro-objects 120 are provided in a physical channel 2702 and then distributed by virtual channels 2704 from the physical channel 2702 to the outputting mechanisms 2606. As noted, the processing mechanism 2604 can be the same as or similar to the processing mechanism 110. The processing mechanism 2604 can thus comprise the OET apparatus 3400 illustrated in FIG. 4, and the virtual channels 2704 can be selectively created by a series of one or more different light patterns 418 (see FIG. 4). Alternatively, the channel 2702 can be virtual and the channels 2704 can be physical. As yet another alternative, the channels 2702 and the channels 2704 can each be physical or virtual. As still another alternative, multiple such channels can feed one outputting mechanism 2606. As a yet further alternative, one such channel can feed multiple outputting mechanisms 2606.

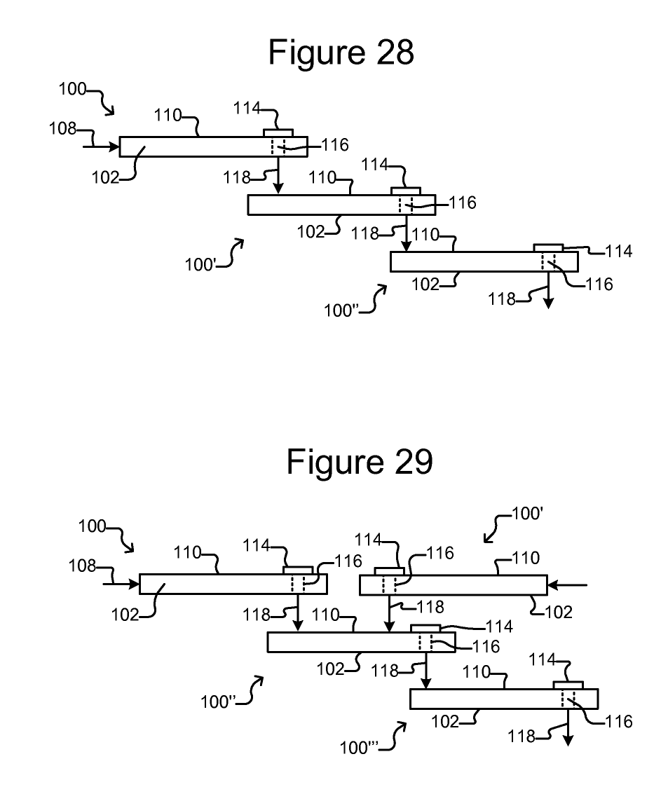

One or more of the processing/outputting devices 100 of FIGS. 1A-1C and/or the processing/outputting devices 2600 of FIG. 26 can be used together (including any variation or particular configuration of the devices 100, 2600 illustrated or discussed herein). FIGS. 28 and 29 illustrate examples according to some embodiments of the invention.

FIG. 28 illustrates an example in which a plurality of the devices 100 (which can instead by like device 2600 or any other device disclosed or illustrate herein) are cascaded. As shown, the output 118 of a first device 100 can be the input to a second device 100′, and the output 118 of the second device 100′ can be the input to a third device 100″. The processing mechanism 110 of each device 100, 100′, and 100″ can perform a different function or the same function. For example, the processing mechanism 110 of the first device 100 can perform a first function on micro-objects 120, which can then be output 118 to the second device 100′. The processing mechanism 110 of the second device 100′ can then perform a second function on the micro-objects 120 received from the first device 100, and the micro-objects 120 can then be output 118 from the second device 100′ to the third device 100″. The processing mechanism 110 of the third device 100″ can then perform a third function on the micro-objects 120 received from the second device 100″.

In one example in which the micro-objects 120 are cells, the first function performed by the processing mechanism 110 of the first device 100 can be to fuse two different cells to form hydridoma cells, which are output 118 to the second device 100′. The second function performed by the processing mechanism 110 of the second device 100′ can be to grow the population of the hydridoma cells received from the first device 100, and then output 118 the cells to the third device 100″. The third function performed by the processing mechanism 110 of the third device 100′″ can be to monitor secretions by individual hydridoma cells received from the second device 100′.

In another example in which the micro-objects 120 are cells, the first function performed by the processing mechanism 110 of the first device 100 can be to select cells based on a selection criterion and then output 118 the selected cells to the second device 100′. The second function performed by the processing mechanism 110 of the second device 100 can be to grow the population of the selected cells received from the first device 100, and then output 118 the cells to the third device 100″. The third function performed by the processing mechanism 110 of the third device 100″ can be to monitor secretions by the individual cells received from the second device 100′.

FIG. 29 illustrates another example in which a plurality of the devices 100 (which can instead by like device 2600) are cascaded. As shown, the output 118 of a first device 100 and the output 118 of a second device 100′ can be the inputs to a third device 100″, and the output 118 of the third device 100″ can be the input to a fourth device 100′″. The processing mechanism 110 of each device 100, 100′, and 100″ can perform a different function or the same function. For example, the processing mechanism 110 of the first device 100 can perform a first function on a first set of micro-objects 120, which can then be output 118 to the third device 100″. The processing mechanism 110 of the second device 100′ can perform a second function on a second set of micro-objects 120, which can then be output 118 to the third device 100″. The processing mechanism 110 of the third device 100″ can then perform a third function on the first set of micro-objects 120 received from the first device 100 and the second set of micro-objects 120 received from the second device 100′. The third device 100″ can then output 118 the micro-objects 120 to the fourth device 100′″, and the processing mechanism of the fourth device 100′″ can perform a fourth function on the micro-objects 120 received from the third device 100″.

In an example in which the micro-objects 120 are cells, the first function performed by the processing mechanism 110 of the first device 100 can be to select cells of a first type based on a selection criterion and then output 118 the selected cells of the first type to the third device 100″. The second function performed by the processing mechanism 110 of the second device 100′ can be to select cells of a second type based on a selection criterion and then output 118 the selected cells of the second type to the third device 100″. Output 118 from the first device 100 and output 118 from the second device 100′ can but need not be at the same time. The third function performed by the processing mechanism 110 of the third device 100″ can be to fuse a cell of the first type (received from the first device 100) with a cell of the second type (received from the second device 100′). The third device 100″ can then output 118 the fused cells to the fourth device 100′″. The fourth function performed by the processing mechanism 110 of the fourth device 100′″ can be to hold the fused cells, for example, to grow the population of the fused cells or monitor the fused cells. Another example of a function that can be performed in the fourth device 100′″ or any of the devices 100, 100′, 100″ is adding different reagents to the cells or groups of cells and then determining the reaction of the cells to the reagents.

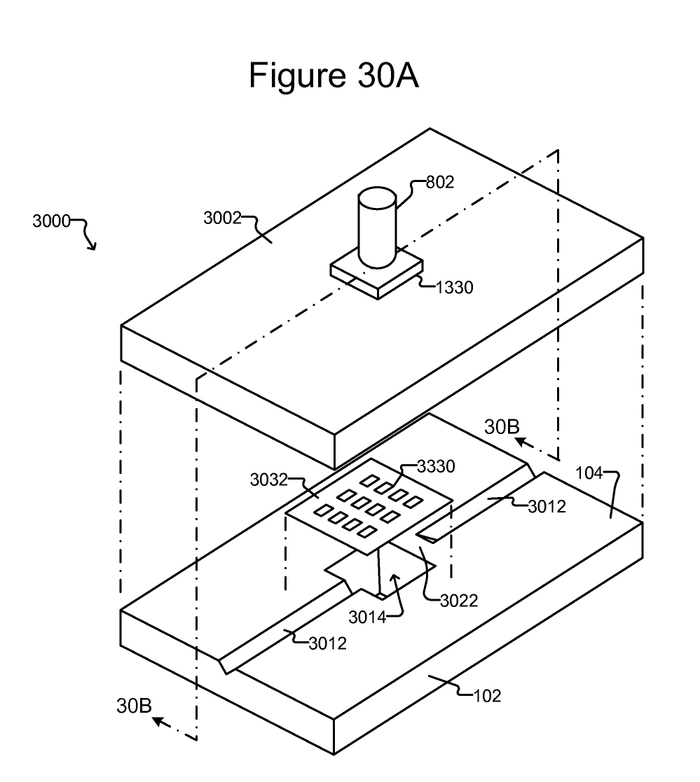

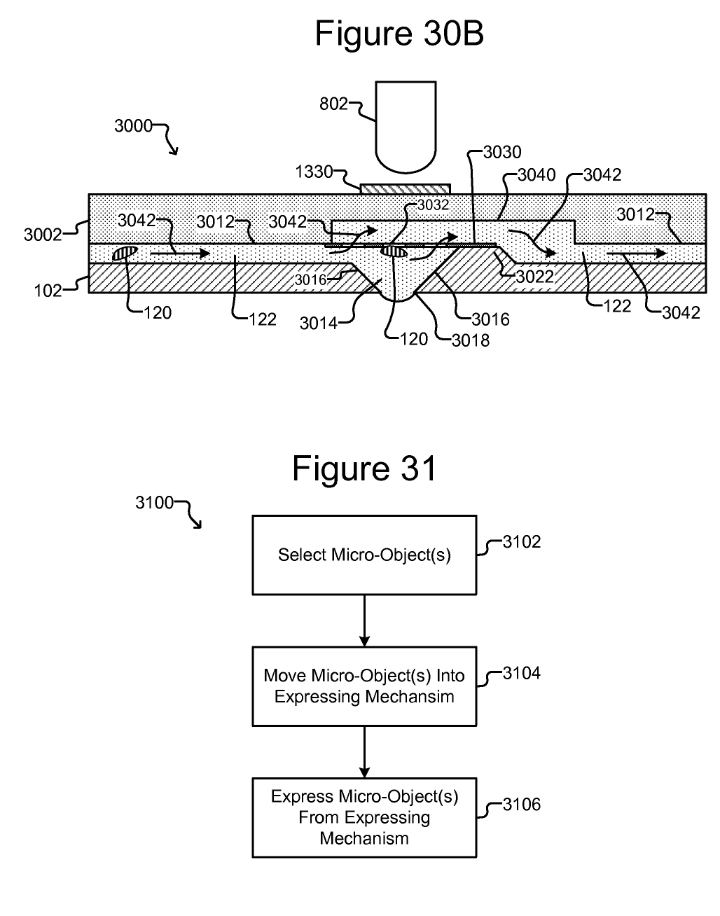

FIG. 30A shows an exploded perspective view and FIG. 30B a side cross-sectional view of a processing/outputting micro-fluidic device 3000 according to some embodiments of the invention. As shown, the device 3000 can comprise the base 102 and a flexible structure 3002, which can be generally like flexible structure 1306 and can, for example, comprise any of the materials discussed above with respect to the flexible structure 1306. As also shown, channels 3012 can lead into and out of a nozzle 3014 and reservoir 3040. As shown, the nozzle 3014 can be defined by sloped sidewalls 3016 in the base 102 that lead to an exit opening 3018 in the base 102, and the reservoir 3040 can be defined in the flexible structure 3002. Alternatively, the nozzle 3014 can also be defined in part in the flexible structure 3002, and/or the reservoir 3040 can also be defined in part in the base 102. The channels 3012 can, for example, comprise “V” shaped trenches in the base 102, and all or part of the nozzle 3014 can comprise the cavity in the base 102 to the exit opening 3018. As shown, there can be a wall 3022 between the nozzle 3014 and one of the channels 3012.

As shown in FIG. 30B, the reservoir 3040 can be disposed at least in part adjacent the nozzle 3014. A barrier 3030 comprising holes 3032 can be disposed between the reservoir 3040 and the nozzle 3014. As shown in FIG. 30B, medium 122 can flow 3042 from a first of the channels 3012 into the cavity of the nozzle 3014, through the holes 3032 in the barrier 3030, past the wall 3022, and out a second of the channels 3012. The flow 3042 can carry a micro-object 120 to the barrier 3030. The holes 3032 in the barrier 3030, however, can be smaller than the micro-object 120 so that the micro-object is trapped at the barrier 3030 above the nozzle 3014. While a micro-object 120 is trapped at the barrier 3030, a striking mechanism 802 can strike a cap structure 1330 disposed on the flexible structure 3002 as discussed above, which can express the micro-object 120 trapped at the barrier 3030 in a droplet of the medium 122 through the exit opening 3018 also generally as discussed above.

Alternatively, once a micro-object 120 is trapped at the barrier 3030, the micro-object 120 can be allowed or caused (e.g., by reducing or stopping the flow 3042) to sink towards the bottom of the nozzle 3014 (e.g., near the exit opening 3018). Then, when the micro-object 120 has sunk into the nozzle 3014 (e.g., is near the bottom of the nozzle 3014, for example is near the exit opening 3018), the striking mechanism 802 can strike the cap structure 1330 as discussed above, expressing the micro-object 120 in a droplet of the medium 122 through the exit opening 3018 as discussed above.

In FIGS. 30A and 30B, a combination of one or more of the cap structure 1330, the flexible structure 3002, the nozzle 1316, the reservoir 3040, and the exit opening 3018 can be an example of the expressing mechanism 804. The nozzle 1316 and/or the exit opening 3018 can be an example of the output passage 116.

In some embodiments, a device like device 2600 of FIG. 26 with multiple outputting mechanisms 2606 can be configured with the channel 3012, nozzle 3016, barrier 3030, and reservoir 3040 of FIGS. 30A and 30B. For example, each outputting mechanism 2606 in FIG. 26 can be configured as a nozzle 3014 with an exit opening 3018 and a reservoir 3040 with a barrier 3030 between the nozzle 3014 and reservoir 3040 as shown in FIGS. 30A and 30B, and the device 2600 can be configured with a channel 3012 leading into each such nozzle 3014 and a channel 3012 leading out of each such reservoir 3040 as illustrated in FIGS. 30A and 30B. Although there are five outputting mechanisms 2606 illustrated in FIG. 26, there can be fewer or more. In some embodiments, there can be many more such outputting mechanisms 2606 (e.g., one hundred or more). In operation, the device 2606 configured with the features of FIGS. 30A and 30B can be configured to direct cells 120 into each such nozzle 3014. Then, after there is at least one cell 120 trapped in the barriers 3040 (or nozzles 3016) of at least a desired number (e.g., all of) of the outputting mechanisms 2606, the outputting mechanism 2606 can be activated to express the trapped cells 120 in droplets (as discussed above) simultaneously.

FIG. 31 illustrates a process 3100 that is an example of operation of any of the processing/outputting devices illustrated in the figures or discussed herein.

As shown, at step 3102, the process 3100 can select one or more micro-objects 122. Step 3102 can be performed with the processing mechanism 110 generally in any way discussed above. For example, step 3102 can be performed with the OET apparatus 400 of FIG. 4, for example, as illustrated in FIG. 5 or 6 and discussed above with respect to those figures.

At step 3104, the process 3100 can move the selected micro-object(s) 122 into the outputting mechanism 114. Alternatively, step 3102 can be skipped or not included in process 3100, in which case one or more micro-objects 122 can be moved into the outputting mechanism 114 regardless of whether those micro-objects 122 were previously selected. Regardless of whether step 3102 is performed, step 3104 can be performed by moving one or more micro-objects 122 in any manor discussed above.

At step 3106, the micro-object(s) 122 moved into the expressing mechanism 114 can be expressed in a droplet 126, which can be accomplished in any manor discussed above.

Although specific embodiments and applications of the invention have been described in this specification, these embodiments and applications are exemplary only, and many variations are possible.

We claim:

1. A process of expressing a micro-object in a droplet of liquid medium, said process comprising:
moving a micro-object in a liquid medium into an expressing mechanism disposed on a base having an output passage therein; and
expressing said micro-object in a droplet of said medium through said output passage by striking said expressing mechanism with sufficient force to express said droplet through said output passage.

2. The process of claim 1 further comprising, prior to said moving, selecting said micro-object outside of said expressing mechanism from a plurality of micro-objects in said liquid medium.

3. The process of claim 1 further comprising, prior to said moving, selecting outside of said expressing mechanism any desired number from one and at least ten of a plurality of micro-objects in said medium, wherein:
said moving comprises moving said selected micro-object(s) into said expressing mechanism; and
said expressing comprises expressing said selected micro-object(s) in said droplet.

4. The process of claim 3, wherein:
said selecting comprises directing a light cage around said selected micro-object(s) and onto a photoconductive material disposed on said base; and
said moving comprises moving said light cage into said expressing mechanism.

5. The process of claim 3, wherein said selecting comprises utilizing dielectrophoresis to trap said selected micro-object(s).

6. The process of claim 3, wherein:
said selecting comprises trapping said selected micro-object(s) with an optoelectronic tweezers (OET) device, and
said moving comprises moving said selected micro-object(s) with said OET device.

7. The process of claim 1, wherein said moving comprises creating a flow of said medium into said expressing mechanism from a first channel and out of said expressing mechanism through a second channel.

8. The process of claim 7, wherein said moving further comprises trapping said micro-object at a barrier adjacent said output passage.

9. The process of claim 8, wherein:
said barrier comprises holes through which said medium flows, and
said holes are smaller than said micro-object.

10. The process of claim 9, wherein:
said output passage comprises a nozzle in said base,
said nozzle and a reservoir of said liquid medium are disposed between said first channel and said second channel, and
said barrier is disposed between said nozzle and said reservoir.

11. The process of claim 7 further comprising:
sensing a position of said micro-object in said flow, and
said expressing comprises triggering said expressing mechanism to output said micro-object in accordance with said sensed position of said micro-object and a rate of said flow.

12. The process of claim 7 further comprising slowing said flow of said medium adjacent an inlet to said expressing mechanism.

13. The process of claim 1, wherein:
said expressing mechanism comprises a flexible structure that, with at least said base, defines a reservoir, wherein said reservoir is fluidically connected to said output passage in said base and configured to contain a quantity of said medium, and
said striking comprises striking said flexible structure with sufficient force to express medium from said reservoir towards said output passage and thereby express said droplet through said output passage.

14. The process of claim 13, wherein said striking comprises:
moving a free end of a cantilevered beam spring away from said flexible structure, and
releasing said free end.

15. The process of claim 13, wherein said expressing mechanism comprises a cap structure disposed on said flexible structure, and said striking comprises directly striking said cap structure.

16. The process of claim 13, wherein:
said reservoir and said output passage are sized and positioned such that said liquid medium forms a meniscus at an exit opening of said output passage, and
said striking comprises striking said flexible structure with sufficient force to overcome a surface tension of said liquid medium on sidewalls leading to said exit opening.

17. The process of claim 1, wherein said expressing expresses said droplet upward against a force of gravity.

18. A micro-fluidic device comprising:
an expressing mechanism disposed on a base having an output passage therein; and
a striking mechanism configured to strike said expressing mechanism with sufficient force to express a droplet of liquid medium from said expressing mechanism through said output passage.

19. The device of claim 18 further comprising a selecting mechanism configured to select any desired number from one and at least ten of a plurality of micro-objects in said medium outside of said striking mechanism.

20. The device of claim 19, wherein said selecting mechanism is further configured to move said selected micro-object(s) into said expressing mechanism.

21. The device of claim 20, wherein said selecting mechanism comprises:
a photoconductive material disposed on said base, and
a light source controllable to direct a light cage onto said photoconductive material and around said selected micro-objects.

22. The device of claim 21, wherein said light source is further controllable to move said light cage into said expressing mechanism.

23. The device of claim 19, wherein said selecting mechanism comprises an optoelectronic tweezers device.

24. The device of claim 19, wherein said selecting mechanism is disposed on said base.

25. The device of claim 19, wherein:
said base comprises a first substrate and a second substrate,
said expressing mechanism is disposed on said first substrate,
said selecting mechanism is disposed on said second substrate, and
said selecting mechanism is connected to said expressing mechanism.

26. The device of claim 18 further comprising:
a first channel to said expressing mechanism; and
a second channel from said expressing mechanism.

27. The device of claim 26, wherein said expressing mechanism comprises:
a nozzle,
a reservoir of said medium, and
a barrier with holes therein, wherein said barrier is disposed between said nozzle and said reservoir, and said holes are smaller than said micro-object.

28. The device of claim 27 further comprising a flexible structure, wherein:
said output passage comprises said nozzle, and
said reservoir is formed at least in part in said flexible structure.

29. The device of claim 26, wherein:
said first channel widens immediately adjacent an inlet to said expressing mechanism, and
said second channel narrows immediately adjacent an outlet from said expressing mechanism.

30. The device of claim 26 further comprising a sensor configured to detect at a position outside of said expressing mechanism said micro-object in a flow of said medium in said first channel and thereafter trigger said striking mechanism to strike said expressing mechanism after said micro-object has flowed into said expressing mechanism.

31. The device of claim 18, wherein said striking mechanism comprises:
a spring disposed to strike said expressing mechanism, and
an actuator configured to bend and then release said spring.

32. The device of claim 31, wherein:
said spring comprises a cantilevered beam, and
said actuator is configured to bend said spring by moving a free end of said beam away from said expressing mechanism and then to release said spring by releasing said free end.

33. The device of claim 18 further comprising:
a flexible structure disposed on said base, and
a reservoir of said medium disposed between said flexible structure and said base, wherein
said reservoir is fluidically connected to said output passage.

34. The device of claim 33, wherein:
said output passage is from a first wall of said reservoir through said base; and
said first wall of said reservoir is at least two times larger than an opening of said output passage at said first wall.

35. The device of claim 33, wherein:
said output passage in said base comprises an exit opening in said base,
sidewalls of said reservoir slope from an opening in a first surface of said base to said exit opening, and
said opening in said first surface is larger than said exit opening.

36. The device of claim 33, wherein said reservoir is spaced laterally from said output passage, wherein said device further comprises a fluidic feed from said reservoir to said output passage.

37. The device of claim 18, wherein:
said flexible structure and said base define a first channel to a first portion of said reservoir and a second channel away from a second portion of said reservoir,
said output passage is a first output passage, which is from said first portion of said reservoir through said base to a common space,
said base has a second output passage, which is from said second portion of said reservoir through said base to said common space.

38. The device of claim 37, wherein said flexible structure comprises a divider structure separating said first portion of said reservoir from said second portion.
